(19) United States
(12) Patent Application Publication
(10) Pub. No.: US 2007/0043135 A1
(43) Pub. Date: Feb. 22, 2007

(54) Radiation curable coating formulations comprising polyesters

(76) Inventors: Seymour Preis, Allentown, PA (US); Richard G. Herman, Whitehall, PA (US); Jean S. Lavelle, Coopersburg, PA (US); James E. Roberts, Bethlehem, PA (US)

Correspondence Address: COMPETITIVE TECHNOLOGIES, INC., 777 COMMERCE DRIVE, FAIRFIELD, CT, 06825, US

(21) Appl. No.: 11/506,529

(22) Filed: Aug. 18, 2006

Related U.S. Application Data
(60) Provisional application No. 60/709,483, filed on Aug. 19, 2005.

(51) Int. Cl. G03F 7/031

(52) U.S. Cl. 522/8

(57) ABSTRACT

An energy curable coating formulation comprising oligomeric acrylate and polyester, and optionally multifunctional monomer is provided. Additional optional ingredients include photoinitiators, wetting agents, flow and leveling agents, fillers, and coloring components. Also provided are methods of forming a coating on a substrate, and resulting coatings.

### RELATED APPLICATIONS

This application claims the benefit of priority under 35 U.S.C. 119(e) to copending U.S. Provisional Application No. 60/709,483, filed on Aug. 19, 2005, the entire contents of which are incorporated herein by reference

### FIELD OF THE INVENTION

The present invention relates to radiation curable coatings, and in particular to radiation curable coatings in which a portion of the acrylate oligomer is replaced by a polyester.

### BACKGROUND OF THE INVENTION

The energy curable processes of commercial importance to coatings and adhesives are ultraviolet (UV) energy or electron beam energy (EB). Typical commercial UV/EB formulations used in these applications contain acrylate oligomeric resins, low viscosity reactive acrylate polyfunctional crosslinking monomers (polyfunctional monomers), pigments as required, and photoinitiators as needed. The UV or EB energy provides free radical generating irradiation. The free radicals initiate the curing, or in other words, the rapid polymerization and crosslinking of the various unsaturated components. While EB curing needs no activators or initiators, as its energy is sufficient to produce free radicals directly, UV curing essentially requires photoinitiators specifically present in the formulation. As is well known, the photoinitiators upon the UV exposure are cleaved to yield the initiating free radicals. The latter method has been in commercial existence since the late 1960s, while EB curing technology, because of its initial capital expense and development cost, has a more recent competitive presence. Thus, EB formulations are very similar to the UV formulations, except for the absence of photoinitiators in EB formulations.

Current EB/UV formulations work efficiently, but the acrylate oligomers are relatively expensive and often have poor pigment wetting properties. Another disadvantage associated with acrylate formulations is their distinct and often-unfavorable odor upon exposure (for example, as encountered in a pressroom), and in some cases chemical sensitivity and respiratory health issues result.

Thus, there is a need for substitutes for acrylate oligomers which are cheaper, which have improved pigment wetting properties, and which are less odorous and possess less deleterious effects on health.

### SUMMARY OF THE INVENTION

Therefore, it is an object of the present invention to provide radiation curable coating formulations comprising an oligomeric acrylate and a polyester; thus, a portion of the oligomeric acrylate present in current conventional radiation curable coating formulations is replaced by a polyester in formulations of the present invention. In some embodiments, the formulations further comprise a multifunctional monomer. These formulations of the present invention are cheaper, have improved pigment wetting properties, and are less odorous and environmentally safer when compared to currently available radiation curable coating formulations.

It is a further object to provide methods of preparing films from the radiation curable coatings as described above.

It is yet a further object of the present invention to provide films prepared from radiation curable coatings as described above.

Thus, in one aspect, the present invention provides an energy curable coating formulation comprising an oligomeric acrylate and a polyester, where the oligomeric acrylate is a single type of oligomeric acrylate or a mixture of oligomeric types, and where the polyester is a single type of polyester or a mixture of polyesters. In some embodiments, the relative proportion of the oligomeric acrylate and the polyester based on weight is from about 99% to about 50% for the oligomeric acrylate, with various preferred ranges of from about 95% to about 50%, from about 85% to about 50%, from about 85% to about 60%, and from about 80% to about 60%, and from about slightly more than about 0% to about 50% for the polyester, with various preferred ranges from about 5% to about 50%, from about 15% to about 50%, from about 15% to about 40%, and from about 20% to about 40%, such that the proportion of polyester is about equal to or less than the proportion of oligomeric acrylate present and the total proportion of oligomeric acrylate and polyester together is about 100%.

In further embodiments, the energy curable coating formulation further comprises a multifunctional monomer, where the multifunctional monomer is a single type of monomer or a mixture of monomers. In some further emodiments, the relative proportion of the oligomeric acrylate, the polyester, and the multifunctional monomer based on weight is from about 55% to slightly less than 100% for the oligomeric acrylate, from about slightly more than 0% to about 50% for the polyester, such that the proportion is about equal to or less than the proportion of oligomeric acrylate present, and from about 0% to about slightly less than about 45% for the multifunctional monomer, such that the total proportion of oligomeric acrylate, polyester, and multifunctional monomer together is about 100%.

In further embodiments, any of the formulations described above further comprise a photoinitiator. In yet further embodiments, any of the formulations described previously further comprise at least one ingredient selected from the group consisting of monofunctional monomers, wetting agents, flow and/or leveling agents, fillers, and coloring components, where the ingredient comprises a single type of ingredient or a mixture of types of ingredients.

In another aspect, the present invention provides a method of preparing any of the coating formulations described above, comprising combining an oligomeric acrylate and a polyester, preferably in the proportions as described above; further embodiments comprise combining an oligomeric acrylate and a polyester with a photoinitiator. In other embodiments, the method of preparing a coating formulation as described above comprises combining an oligomeric acrylate, a polyester, and a multifunctional monomer, preferably, in the proportions as described above; further embodiments comprise combining an oligomeric acrylate and a polyester with a photoinitiator. In yet further embodiments, a method of preparing a coating formulation as described above comprises combining an oligomeric acrylate, and polyester, a multifunctional monomer, and any of the optional additional ingredients, as described above.

In yet another aspect, the present invention provides a method for forming a coating on a substrate, comprising providing an energy curable coating formulation as described above, applying said composition to a substrate, and exposing said composition to a source of radiation to resulting in an energy cured coating on the substrate.

In yet another aspect, the present invention provides a coating comprising a radiation cured formulation, where the formulation is any formulation as described above. In other aspects, the present invention provides a coating prepared according to any of the methods described above.

In yet another aspect, the present invention provides a radiation-polymerizable composition comprising an oligomeric acrylate and a polyester. In some embodiments, the relative proportion of the oligomeric acrylate and the polyester based on weight is from about 99% to about 50% for the oligomeric acrylate, and from about slightly more than about 0% to about 50% for the polyester, such that the proportion of polyester is about equal to or less than the proportion of oligomeric acrylate present and the total proportion of oligomeric acrylate and polyester together is about 100%. In further embodiments, the composition further comprises a multifunctional monomer. In some embodiments, the relative proportion based on weight of the oligomeric acrylate, the polyester, and the multifunctional monomer is from about 55% to slightly less than 100% for the oligomeric acrylate, from about slightly more than 0% to about 50% for the polyester, such that the proportion is about equal to or less than the proportion of oligomeric acrylate present, and from about 0% to about slightly less than about 45% for the multifunctional monomer, such that the total proportion of oligomeric acrylate, polyester, and multifunctional monomer together is about 100%.

In further embodiments, any of the radiation-polymerizable compositions described above further comprise a photoinitiator. In yet further embodiments, any of the radiation-polymerizable compositions described previously further comprise at least one ingredient selected from the group consisting of monofunctional monomers, wetting agents, flow and/or leveling agents, fillers, and coloring components, where the ingredient comprises a single type of ingredient or a mixture of types of ingredients.

In yet another aspect, the present invention provides a method of preparing any of the radiation-polymerizable compositions described above, comprising combining an oligomeric acrylate and a polyester, preferably in the proportions as described above; further embodiments comprise combining an oligomeric acrylate and a polyester with a photoinitiator. In other embodiments, the method of preparing a coating formulation as described above comprises combining an oligomeric acrylate, a polyester, and a multifunctional monomer, preferably, in the proportions as described above; further embodiments comprise combining an oligomeric acrylate and a polyester with a photoinitiator. In yet further embodiments, a method of preparing a radiation-polymerizable composition as described above comprises combining an oligomeric acrylate, and polyester, a multifunctional monomer, and any of the optional additional ingredients, as described above.

In yet another aspect, the present invention provides a method for forming a coating on a substrate, comprising providing a radiation-polymerizable composition as described above, applying said composition to a substrate, and exposing said composition to a source of radiation to resulting in an energy cured coating on the substrate.

### BRIEF DESCRIPTION OF THE FIGURES

FIG. 1 shows the film cure energy requirement versus oil length in a simplified two component test series.

FIG. 2 shows the film hardness versus oil length in a simplified two component test series.

### Definitions

To facilitate an understanding of the present invention, a number of terms and phrases are defined below. As used herein:

The term “coating formulation” and the like refer to a composition that can be applied to a surface and processed to result in a thin film on the surface. Uses of coating formulations are provided in the description below. A coating formulation may further act as an adhesive between two similar or different surfaces or substrates when the substrates or surfaces are sufficiently radiation energy transparent.

The terms “radiation curable” or “energy curable” and the like refer to a process of drying a surface applied coating formulation by means of applying energy in the form of radiation; the resulting surface film comprises polymerized and/or cross-linked components of the applied coating formulation. Surface films may also be referred to as dried or cured formulations or coatings. Radiation includes ultraviolet (UV) and electron beam (EB) radiation.

The term “type” when referring to an ingredient of a coating formulation refers to an ingredient prepared and/or sold separately. A “mixture” of an ingredient types refers to more than one type of the ingredient present in the formulation.

The term “acrylate oligomer” and the like refer to multi-acrylated oligomers which are currently generally employed in most energy curable coating formulations. These acrylated oligomers, also referred to as prepolymers, oliogmeric acrylates, or acrylate oligomeric resin, together with the multifunctional monomers generally make up the crosslink network of UV/EB cured films; they are also responsible for developing the relatively higher crosslink density of UV/EB cured films. The molecular weights of the acrylated oligomers range from about 400 to about 1500, with some at about 2500 and some at about 5000; the higher molecular weight acylated oligomers generally exhibit good coating flexibility.

The term “multifunctional monomer” refers to a simple generally low molecular weight molecule with more than one functional group, of which two or more up to all can polymerize and crosslink typically primarily via their unsaturated bonds.

The term “polyester” when used in reference to a formulation of the present invention refers to a condensation product between a polyol, usually having an average functionality about equal to or greater than about three and at least one polybasic acid with an average functionality of about two. The polyester is ungelled. The polyol is preferably a polyhydric alcohol, but may also include, in a formal sense, an epoxy resin backbone which allows the generation of an epoxy ester. The acid is preferably a dibasic acid or its anhydride; the latter may be further modified with a less reactive monofunctional acid. The polyester also comprises acyl groups, where at least some to most of the acyl groups comprise at least one internal double bond. The presence of a single double bond in an acyl group is referred to as a “monounsaturated acyl group,” or “monounsaturated,” while the presence of two or more internal double bonds is referred to as a “polyunsaturated acyl group,” or “polyunsaturated.” The acyl groups range in size from 8 to 28 carbons in length, preferably from about 12 to about 22 carbons in length, and most preferably from about 16 to about 18 carbons in length, and possess at least one internal double bond. In some embodiments, acyl moieties of about 18 carbons in length are present in the highest proportion of total acyl moieties.

The mole ratio of polyol hydroxyl groups to acid groups of the dibasic acid components are usually at least about three to two, and may have a ratio of greater than about three to two, for example, to prevent gelling. The essential reactive equivalent, as is well known in the art, is utilized in estimating the mole ratio. For example, pthhalic acid anhydride is equivalent to two, and an equal molar amount of ethylene glycol and pentaerythritol have an equivalent of three. The remaining polyol hydroxyl groups are bonded to a partial or full extent, preferably to pendent ester-linked acyl groups, and the further remaining unreacted hydroxyl groups may also be bonded, at least to a partial extent, to monobasic acids other than acyl groups, and the final remaining hydroxyl groups are left free. The polyol chain backbone is identified as a polyester type, and the polyesters may be referred to as “alkyd-polyesters.” Epoxy esters, as described above, are also included in the definition of polyesters in the context of the present invention.

In some embodiments, the polyesters are polyester chains branch functionalized via an ester link with unsaturated fatty acids. These polyesters are also referred to as chain polyesters containing fatty acid side-branches, fatty acid chain branched polyesters, fatty acid functionalized polyesters, and fatty acid side-branched polyesters, side-branched polyesters, and the like. In some embodiments, side-branched polyesters are based on natural source triglycerides or their constituent fatty acids. In some preferred embodiments, the side-branched polyester is a polyester derived from plant oils. These triglycerides include but are not limited to drying or semidrying vegetable oils, including linseed oils, soybean and sunflower oils, and dehydrated castor oils. The proportion of unsaturated fatty acids in these oils may range up to equal to or greater than about 90% of the total fatty acid present. The tall oil fatty acids (TOFA) derived from pine oils and obtained via subsequent processing including a saponification step is another source of fatty acids for the polyesters of the present invention. Thus, in some embodiments, the source fatty acids include, but are not limited to, octanoic acid, decanoic acid, dodecanoic acid, hexadecanoic acid, octadecanoic acid, cis-9-octadecanoic acid (oleic acid), 12-hydroxy-cis-9-octadecanoic acid (ricinoleic), cis-9, cis-12-octadecadienoic acid (linoleic acid), cis-9, cis-12, cis-15-octadecatrienoic acid (linolenic acid), cis-9, trans-11, trans-13-octadecatrienoic acid (eleosteric acid), 5, 8, 11, 14-docosatetraenoic acid and cis-13-docosanoic acid, and conjugated forms of these polyunsaturated fatty acids such as may be derived from linoleic and linolenic acid. The source fatty acids, prior to their incorporation into a polyester, may be free or combined as part of a mono- to triglyceride unit.

In many commercial embodiments, the polyester unsaturated fatty acid components are oleic, linoleic, and linolenic acids, and the processed conjugated and non-conjugated derivatives derived essentially from a natural source of 18 carbon fatty acids, as for example from castor oil. These identified fatty acids have predominantly a cis configuration. Other configurations are also included in the fatty acid moieties of the polyesters of the present invention; these configurations include but are not limited to various cis and trans and linear isomerized, dimerized, and conjugated fatty chain products that may be present in the source oils or that may be formed during oil and/or fatty acid isolation, as for example in dehydrated castor oil, or during the polyester formation process as described in more detail below. Typically, these other configured fatty acids are not present in major amounts.

The iodine number or value may further characterize the fatty acids of the fatty acid side-branched polyesters of the present invention. The iodine number or value determination is used to ascertain the extent to which the carbon-carbon bonds of the product in questions can be regarded as saturated or unsaturated. In principle, it involves determining how many grams of iodine can be absorbed per 100 grams of sample under defined conditions (grams I₂/100 grams of sample). Thus, an iodine number or value can be determined for samples of oil or fatty acids used to prepare the side-branched polyesters or of the side-branched polyesters of the present invention, and is a measure of the degree of unsaturation of the sample. In preferred embodiments, the iodine number of the aggregate fatty acid source for a polyester of the present invention is greater than about 100; in more preferred embodiments, the iodine number is greater than about 125; in yet more preferred embodiments, the iodine number is greater than about 150; in yet other preferred embodiments, the iodine number ranges from about 100 to about 210; in yet other preferred embodiments, the iodine number ranges from about 150 to about 190. The iodine number of the resulting polyester prepared from such diverse fatty acid sources is less, and preferably in the range of about 60 to about 125.

In other embodiments, polyesters of the present invention comprise other polymeric backbones. Thus, in some embodiments, free fatty acids or fatty acids existing as part of a mono- to triglyceride unit may be attached to the other polymeric backbones resulting in a polyester product with an iodine number in the ranges described above. In particular embodiments, bisphenol A diepoxy resins yield epoxy ester resins upon reaction with source fatty acids as described above, resulting in a product with pendent fatty acid moieties and an iodine number in the range as described above. These products provide a reactive component in a radiation curable formulation of the present invention. The secondary or ancillary hydroxyl groups formed as a result of epoxy ring opening are also available to react with the fatty acids.

Thus, in different embodiments, the polyesters comprise triglycerides or free fatty acids esterified into hydroxy functional chain polyesters providing fatty acid branching; in preferred embodiments, the polyester has a ratio of polyol hydroxyl groups to acid groups of the dibasic acid of at least about three to two allowing an attachment accommodation of the fatty acid side groupings or chains. In other embodiments, triglyceride fatty acids or free fatty acids are attached to another polymeric backbone, such as an advancing epoxy resin, resulting in a resin comprising functionalized branches with fatty acid groups.

### DESCRIPTION OF THE INVENTION

The present invention relates to radiation curable coating formulations and resulting coating films, and in particular to radiation curable coating formulations in which a portion of the oligomeric acrylate is replaced by a polyester as defined herein. In preferred embodiments, the polyester has an alkyd type backbone with pendent ester-linked fatty acid moieties; in more preferred embodiments, at least some to most of the fatty acids are unsaturated, and preferably are derived from plant oil fatty acids.

Multi-acrylated oligomers are currently generally employed in most energy curable coating formulations. These acrylated oligomers, also referred to as prepolymers, oliogmeric acrylates, or oligomeric acrylate resins, often with the multifunctional monomers, generally make up the polymerized network of radiation or UV/EB cured films; they are also responsible for developing the relatively higher crosslink density of UV/EB cured films. The molecular weights of the acrylated oligomers typically range from approximately 400 to approximately 1500, although some may range as high as about 2500 up to about 5000. The higher molecular weight oligomers offer good flexibility. The unsaturated functionality of commercial acrylated oligomers generally ranges from about 2 to about 6.

The present invention is based upon the discovery that polyesters as defined herein can be substituted for a portion of the acrylated oligomers present in most energy curable coating formulations. Surprisingly, polyesters comprising unsaturated acyl side groups, as for example fatty acyl groups derived from plant oils, possess UV/EB curing responsiveness with sufficient reactivity for use as a partial replacement of the acrylated oligomers in energy curable formulations and coatings. Even more surprisingly, for several embodiments of coating formulations of the present invention, the curing rates are enhanced. Moreover and unexpectedly, the characteristics of the resulting films are about equivalent to those of the formulations without the presence of the polyesters.

This discovery was unexpected, as conventional wisdom holds that drying or processing of conventional energy curable coating formulations involves polymerization via radical reactions of the applied coating formulation, and that external double bonds always react faster than internal double bonds. By external double bond it is meant that the double bond is exactly at the end of a chain, whereas an internal double bond exists inside of a chain, as for example in a pendent fatty acyl group of a polyester as defined herein. It was further believed that only rarely would an internal double bond be active, as for example when it is adjacent to a carbonyl group or another double bond (as in a conjugated fatty acid).

In contrast, the inventors have discovered that polyesters as defined herein, with acyl groups comprising internal double bonds, can replace a portion of acrylate oligomers in conventional coating formulations. Exemplary but non-limiting acyl groups with internal double bonds include fatty acids derived from plant oils, such as oleic, linoleic, and linolenic. Exemplary but non-limiting examples of compounds with external double bonds include the acrylate oligomers; in coating formulations of the present invention, a portion of the acrylate oligomers are replaced by the polyesters with internal double bonds. Thus, coating formulations of the present invention comprise components previously believed to be inapplicable to or unsuitable for radiation cured coatings.

While it is not necessary to understand the underlying mechanism, and the invention is not intended to be limited to any particular hypothesis or mechanism, it is believed that internal double bonds of the polyester acyl groups are activated in the presence of particular external double bonds, resulting in faster polymerization and crosslinking of the internal double bonds. It is further believed that polymerization of coating formulations of the present invention is not oxygen mediated. Thus, it is conjectured that this newly discovered reactivity of the polyesters resides in the internal double bonds of the fatty acyl side chains; although internal double bonds are generally assigned low reactivity, it appears that their polymerization and crosslinking is synergized by the presence of external double bonds in acrylate oligomers, and that up to about one-third to about one-half of the acrylate oligomers present in a conventional energy curable coating formulation can be replaced with these polyester components with essentially no loss in performance. It is further conjectured that this unexpected increase in reaction rates of energy curable coating formulations of the present invention comprising polyesters with internal double bonds is similar to the generalized speedup effect of copolymerization chemistry (see, for example, C. Hagiopol, “Copolymerization: Toward a Systematic Approach,” Kluwer Academic/Plenum Publishers, New York, 1999), in which the rate of polymerization of two mixed radical monomers is more rapid then the separate rate of each alone.

Thus, the present invention provides energy curable coating formulations in which a portion of acrylated oligomers are replaced by polyesters, preferably comprising unsaturated acyl groups, and more preferably where the unsaturated acyl groups are derived from plant oils.

In preferred embodiments, polyesters comprise a chain polyester functionalized with fatty acid side groups obtained from a drying or a semidrying plant oil, including but not limited to soybean or sunflower oil, tall oil fatty acids (TOFA), or dehydrated castor oil (DCO), and where the polyol preferably has a mole ratio of hydroxyl groups to carboxyl groups of an active dibasic acid of at least about three moles of polyol hydroxyl groups to about two moles of dibasic acid carboxyl groups, and more preferably somewhat greater then this to more readily accommodate esterification with fatty acid side groupings or chains. In further preferred embodiments, the conventional polyesters include the ‘neat’, non-additive, essentially a non-solvent containing polyester, as for example the long oil or the medium oil type, prepared for example by the common monoglyceride process. In other embodiments, coating formulations of the present invention comprise polyesters made with either triolein (CAS 122-32-7) or its constituent fatty acid, oleic acid, in its relatively pure form as a free fatty acid.

In other aspects, the present invention often provides enhanced pigment dispersion and pre-dispersion as indicated by improvement in the resulting viscosity reduction.

In yet other aspects, the present invention provides methods of making coating formulations of the present invention, and in yet other aspects, the present invention provides methods of using coating formulations of the present invention.

In yet other aspects of the present invention, films or coatings obtained from coating formulations of the present invention are provided.

Coating formulations of the present invention possess several advantages. For example, these formulations comprising polyesters as described herein have applicability in the usual rapid energy curing process required by, for example, overprint clear coatings. Moreover, the described chain polyesters functionalized with fatty acid side groups are less expensive then any acrylate oligomer they replace in the formulations of the present invention, providing a cost benefit advantage. Furthermore, in some formulations of the present invention, pigment wetting and dispersion are improved; thus, for example in embodiments comprising the Phthalo pigments, which are often notoriously difficult to disperse, improved pigment wetting and dispersion permits more efficient manufacturing. Another advantage of coating formulations of the present invention include environmentally improved products, as they comprise renewable resources and because they substantially reduce the well-known acrylate odor, which is often disagreeable and may present a physical health issue, particularly in the pressroom.

Polyesters

In coating formulations of the present invention, the polyesters as defined herein refer to a condensation product between a polyol, usually having an average functionality about equal to or greater than three and at least one polybasic acid. The polyester is ungelled. The polyol is preferably a polyhydric alcohol or similarly functionalized epoxy backbone. The polybasic acid is preferably a dibasic acid or its anhydride and in some embodiments is further modified with monofunctional acid. The free hydroxyl groups left available, in a formal sense, from the polyester condensation of the multifunctional polyol, containing at least three hydroxyls, and the dibasic acid, are further esterified, at least in part, with acyl groups which preferably comprise fatty acids, where many to most of the acyl groups contain at least one internal double bond. The presence of a single double bond in an acyl group is referred to as a “monounsaturated acyl group,” or “monounsaturated,” while the presence of two or more internal double bonds is referred to as a “polyunsaturated acyl group,” or “polyunsaturated.” The acyl groups range in size from about eight to about twenty-eight carbons in length, preferably from about twelve to about twenty-two carbons in length, and most preferably from about sixteen to about eighteen carbons in length, and some to most posses at least one internal double bond. In some embodiments, acyl moieties of about eighteen carbons in length are present as the highest proportion of total acyl moieties.

The mole ratio of polyol hydroxyl groups to active acid groups is usually at least about three to two or about 1.5:1, and may have a ratio of greater than about three to two, for example, to prevent gelling. The essential reactive equivalent, as is well known in the art, is utilized in estimating the mole ratio. For example, phthalic acid anhydride is equivalent to two, and an equal molar amount of ethylene glycol and pentaerythritol is equivalent to three. Thus, the non-chain polyol hydroxyl groups are bonded to a partial or full extent, preferably to pendent ester-linked acyl groups, and remaining unreacted hydroxyl groups may also be bonded, at least to a partial extent, to monobasic acids other than acyl groups, and the remaining hydroxyl groups are left free.

In some embodiments, polyesters may be referred to as alkyd-polyesters or alkyd-backboned polyesters or the like. In some embodiments, the polyesters are polyester chains branch functionalized via an ester link with fatty acids, of which some to most are unsaturated. These polyesters are also referred to as chain polyesters containing fatty acid side-branches, fatty acid chain branched polyesters, fatty acid functionalized polyesters, fatty acid side-branched polyesters, and polyesters with pendent fatty acid moieties. In some embodiments, the polyesters are based on natural source triglycerides or their constituent fatty acids. In some preferred embodiments, the polyester is derived from plant oils. These triglycerides include but are not limited to drying or semidrying vegetable oils, including linseed oils, soybean and sunflower oils, and dehydrated castor oils (DCO), and mixtures thereof. The proportion of unsaturated fatty acids in these oils may range up to about or greater than about 90%. The tall oil fatty acids (TOFA), which are collected from pine oils and obtained via subsequent processing including a saponification step, are another source of fatty acids for the polyesters of the present invention. The fatty acids may be free or combined as part of a mono-to triglyceride unit.

Thus, in some embodiments, the polyesters comprise a chain polyester functionalized with fatty acid side groups obtained from a drying or a semidrying plant oil. In other embodiments, coating formulations of the present invention comprise polyesters made with triolein (CAS 122-32-7) or its constituent fatty acid, oleic acid, in its relatively pure form as a free fatty acid.

The fatty acids used to prepare and/or present in the polyesters as defined herein may be further characterized by their iodine number or value, as described further below. The iodine number of the resulting polyester is less than that of the source fatty acids, and is generally in the range of at least about 40 to about 125; in preferred embodiments, the iodine number is in the range or greater than about 50 to about 125; and in more preferred embodiments, the iodine number is in the range or greater than about 60 to about 125.

In other embodiments, polyesters of the present invention comprise other polymeric backbones. Thus, in some embodiments, free fatty acids or fatty acids existing as part of a mono- to triglyceride unit may be attached to other polymeric backbones with the resulting polyester product iodine number in the ranges described above. In particular embodiments, bisphenol A diepoxy resins yield epoxy ester resins upon reaction with source fatty acids as described herein, resulting in a product with pendent fatty acid moieties and an iodine number in the range as described above. These products also provide a reactive component in a radiation curable formulation of the present invention. The ancillary hydroxyl groups formed as a result of ring opening are also available to react with the fatty acids. In yet other embodiments, polyesters of the present invention with their chain functionalized fatty acid branches are converted to monomer modified structures, as per urethane-modified polyester, which retains its alkyd backbone. The latter embodiment may also be referred to as a uralkyd.

In preferred embodiments, the polyesters are ‘neat,’ by which it is meant that they are by design solvent free, or have very minimal solvent content or have been solvent stripped. As a result, some of these polyesters are glassy solids at room temperature, with a glass transition temperature often above 100° C. Thus, in these embodiments, the polyesters include the ‘neat’, non-additive, essentially a non-solvent containing polyester, as for example the long oil or the medium oil type, prepared for example by the common monoglyceride process or the fatty acid process.

Fatty acid functionalized polyesters in coating formulations of the present invention encompass all the products that are generically known as alkyds and that are characterized by the iodine number ranges described above, minus any solvents associated with them, including but not limited to carrier solvents and azeotrope solvents. Note that the iodine number is determined either on samples that are solvent free or the contribution to the iodine number of solvent that may be present is subtracted from the determined value. Examples of reactive fatty acid functionalized chain polyesters that are not conventionally considered an alkyd include a polyester made with the triolein triglyceride (CAS 122-32-7) and one made from pure oleic acid, which are both cis-configurations, as well as a polyester made from trielaidin (CAS 537-39-3) and a polyester made from eleadic acid, both of which are trans-configurations. Triolein has an estimated iodine number of about 85, resulting in an iodine number of its polyester slightly below about 60. If saturated fatty acids are present in a commercial preparation of polyester, then the measured iodine number may even be less.

As noted herein, polyesters in coating formulations of the present invention may be characterized by iodine number; this characterization is based upon the degree of unsaturation of the fatty acyl side chains (or branches). Fatty acid functionalized polyesters can also be characterized in a practical manner by a parameter that is defined as oil length. The oil length number, as a percentage, records the amount of side chain ‘fatty acid’ per total yield of polyester. This ‘fatty acid’ number includes aliphatic saturated acids, such as palmitic acid, in addition to unsaturated acids, such as oleic, linoleic, and linolenic acids. Saturated fatty acids are frequently present at less than about 10% of the total fatty acids derived from the natural triglycerides. The total fatty acids are often identified as C₁₈ acids, or fatty acids which are 18 carbons in length, although fatty acids shorter than 18 carbons, such as palmitic acid (which is 16 carbons in length), may also be present. The oil length value is frequently estimated based on the ingredients charged in the cook corrected for the amount of water eliminated in the reaction.

The oil length number calculation expresses its ‘fatty acid’ content as triglycerides. Therefore, as described by W. T. Elliot in “Surface Coatings Raw Materials and their Usage” (1993; Chapman & Hall, p. 100), to obtain the oil length from the percent ‘fatty acid’/‘total yield’ or C₁₈ acid/‘total yield’ it needs to be multiplied by 1.045. An example of a calculation of the relationship between percent of ‘fatty acid’ content and oil length is given as follows:
840 g ‘fatty acid’+92 g glycerol→878 g oil+54 g H₂O; 878/840=1.045.

The 878 is the nominal molecular weight assigned to the most common triglycerides.

The applicable equations as described by Wicks, Jones and Pappas, Op. Cit., p. 268 are as follows:

1. Oil Length=([Weight of “oil”*]/[Weight of Polyester−Water evolved])×100

2. Oil Length=([1.045×weight of ‘fatty acids’*]/[Weight of Polyester−Water evolved])×100
*Note: “Oil” is the charged weight of the triglycerides. The ‘oil’ and the ‘fatty acid’ as utilized in these equations, as indicated, includes the saturated acids and the saturated acid portion of the triglycerides.

For coating formulations of the present invention, it is contemplated that the component polyesters can be characterized as a long oil length, which is about 55% to about 90%, or as a medium oil length, which is about 46% to about 55%; polyesters are preferably characterized by a long oil length.

Polyesters suitable for use in coating formulations of the present invention are available commercially. Exemplary non-limiting polyesters include those described in the Examples and elsewhere throughout the text.

Thus, the polyesters described in the Examples below are commercially available, with the samples described in the Examples obtained from a manufacturing source. They may be the product of one of the various production processes described herein, and modified as necessary in that they are ‘neat’ samples with no added solvent. As indicated, any solvent that may be present in these examples is a result of the azeotropic method applied in the polyester condensation step of the alcoholysis process to remove the produced water. Solvent retained as a result of the azeotrope, for example about 3-8% by weight of xylene, has not been observed to be significantly detrimental to the energy curing process.

The polyesters as described herein are employed in energy curable coating formulations of the present invention as a partial replacement for the more expensive acrylate oligomeric resins found in most commercial energy curable pigmented and non-pigmented formulations. Although it is not necessary to understand the mechanism of the present invention, and it is not intended that the present invention be limited to any particular mechanism or hypothesis, it is hypothesized that the unsaturated bonds of the fatty acid branches participate in the energy curable processing, and allow these polyesters to function as a reactive ingredient in a coating formulation product applicable to almost all substrates.

The use of these polyesters in coating formulations of the present invention results in little or no or loss of cure rate, and in some embodiments results in an enhanced cure rate, when compared to currently available coating formulations without polyesters. Moreover, the presence of these polyesters in formulations of the present invention produces films with generally the equivalent performance as is observed in films prepared from non-polyester containing counterpart formulations. In some embodiments, there may be some decrease in film hardness, and in some embodiments, there may be loss in methyl ethyl ketone (MEK) resistance. Formulations of the present invention comprising epoxy esters or DCO derived esters cure to the higher hardness, but apparently require a higher energy of cure.

Polyester Acyl Groups

Acyl groups suitable for the polyester component of coating formulations of the present invention include hydrocarbon chains from about eight to about twenty-four carbons in length, where some to most have at least one double bond or degree of unsaturation. In preferred embodiments, the hydrocarbon chains are from about fourteen to about twenty-two carbons in length; and in other preferred embodiments, they are from about eighteen to about twenty carbons in length. In other preferred embodiments, the hydrocarbon chains have two or more double bonds. Thus, in some embodiments, the fatty acids include, but are not limited to, octanoic acid, decanoic acid, dodecanoic acid, hexadecanoic acid, octadecanoic acid, cis-9-octadecanoic acid (oleic acid), 12-hydroxy-cis-9-octadecanoic acid (ricinoleic), cis-9, cis-12-octadecadienoic acid (linoleic acid), cis-9, cis-12, cis-15-octadecatrienoic acid (linolenic acid), cis-9, trans-11, trans-13-octadecatrienoic acid (eleosteric acid), 5, 8, 11, 14-docosatetraenoic acid and cis-13-docosanoic acid, and conjugated forms of these fatty acids, such as of linoleic and linolenic acid.

In preferred embodiments, the acyl groups are derived from unsaturated fatty acids. In some preferred embodiments, the unsaturated fatty acid side chains are oleic, linoleic and linolenic acids; the type and percentage of each of the acids in the polyesters can vary substantially. The resulting polyesters can be formulated into energy curable product that can produce coatings with properties similar to those of corresponding formulations without polyesters, including but not limited to cure rates and hardness.

In many commercial embodiments, the polyester unsaturated fatty acid components are oleic, linoleic, and linolenic acids, and the processed conjugated and non-conjugated derivatives derived essentially from a natural source of 18 carbon fatty acids. Such natural sources are preferably plant oils, including but not limited to soybean oil, sunflower oil, linseed oil, castor oil, cottonseed oil, oiticica oil, perilla oil, safflower oil, and tung oil, and any mixtures thereof.

These identified fatty acids have predominantly a cis configuration. Other configurations are also included in the fatty acid moieties of the polyesters of the present invention; these configurations include but are not limited to various cis and trans and linear isomerized, dimerized, and conjugated fatty chain products that may be present in the source oils or that may be formed during oil and/or fatty acid isolation (as for example are found in dehydrated castor oil) or during the polyester formation process as described herein. Typically, these other configured fatty acids are not present in major amounts, except in particular embodiments. For example, eleosteric acid is a reactive conjugated triene of tung oil, and tung oil in a mixture with linseed oil finds particular use as the source of the pendent fatty acid moieties in epoxy esters.

The fatty acids in the polyesters as defined herein may be further characterized by their iodine number or value, or grams of I₂/100 grams of fatty acids or oil or polyester. The iodine number or value determination is used to ascertain the extent to which the bonds of the product in questions can be regarded as saturated or unsaturated. In principle, it involves determining how many grams of iodine can be absorbed per 100 grams of sample under defined conditions. Thus, an iodine number or value can be determined for samples of oil, fatty acids, or polyesters of the present invention, and represents a measure of the degree of unsaturation of the sample.

Methods of obtaining iodine numbers are well known. One frequently used and standardized method (for example, ISO 3961 or ASTM D 1959) is the Wijs method. This method utilizes an iodine-containing Wijs solution and a sodium thiosulfate and indicator solution. It provides relatively exact values mainly for samples which do not contain a very large proportion of conjugated double bonds, and it is also very reproducible. The iodine numbers described for the present invention are based on the Wijs method. In practice, many of the iodine number determinations are made for a mixture of the fatty acid sources and the fatty acid products, yielding a value of the mixture. Another method determines the precise number of unsaturated bonds in the presence of conjugated double bonds; this is the Rosenmund-Kuhnhenn method (ASTM D 1541), which although slightly more complicated, is an accepted alternate procedure to the Wijs method.

Exemplary iodine numbers are reported as follows; variations are due to differences in sample source and processing. Linseed oil: about 190; a linseed oil based alkyd-polyester: about 94; TOFA: about 130 to 150; dehydrated castor oil (DCO): about 125 to 145; a seed triglyceride with about 80% equal mixed acid unsaturation: about 135; a seed triglyceride with about 80% equal mixed acid unsaturation when converted to an alkyd-polyester at about 50% oil length (oil length is described below): about 66; and when converted to an alkyd-polyester at about 60% oil length: about 80. (See Deligny, P and Tuck, N (2000) “Resins for surface coatings (in Alkyds and Polyesters, Vol. II; Oldring, P K T. ed.; Wiley, NY) page 33 and following; Hajela, B. P. et al. (1975) in Paintindia 22(5): 20-24; and Aigbodion, A. I. et al. (2001) in J. Appl. Polymer Science 79: 2431-2438).

In preferred embodiments, the iodine number of the aggregate fatty acid source for the polyesters of the present invention is greater than about 100; in more preferred embodiments, the iodine number is greater than about 125; in yet more preferred embodiments, the iodine number is greater than about 150; in yet other preferred embodiments, the iodine number ranges from about 100 to about 210; in yet other preferred embodiments, the iodine number ranges from about 150 to about 190. As noted above, the iodine number of the resulting polyester is less than that of the source fatty acids, and is in the range of about 60 to about 125.

Polyester Backbones

In some embodiments, the polyol of the polyester backbone, as a single component, is preferably trifunctional, or if it contains a mixture of polyols the average functionality of the mixture is about three, although in some embodiments, the functionality may be greater or less than about three. Examples of polyols include but are not limited to pentaerythritol (PE), 1,1,1-trimethylolpropane (TMP), and mixtures of PE and ethylene glycol (EG) or propylene glycol (PG) or neopentyl glycol. Generally polyfunctional alcohols that can be used to prepare the alkyd backboned polyesters include but are not limited to polyhydric alcohols having two to about six hydroxyl groups per molecule, including but not limited to: dihydric alcohols such as ethylene glycol, 1,2-propylene glycol, 2,3-butylene glycol, 1,4-butanediol, 1,5-pentanediol, and 2,2,-bis(4-hydroxycyclohexyl)propane; trihydric alcohols including but not limited to glycerol, 1,1,1-trimethylolethan, 1,1,1-trimethylolpropane, and 1,2,6-hexanetriol; tetrahydric alcohols such as erythritol, pentaerythritol and alpha-methyl glucoside; and pentahydric and hexahydric alcohols including but not limited to tetramethylolcyclohexanol, dipentaerythritol, mannitol, and sorbitol; polyallyl alcohol; and oxyalkylene adducts such as diethylene glycol, triethylene glycol, and polyethylene glycol. These polyfunctional alcohols can be used as a single component or as a mixture of polyols. These polyfunctional alcohols can be used in either of two processes to prepare the alkyd backboned polyesters, the monoglyceride process, in which glycerol is typically the major polyol, or the fatty acid process (or acidolysis process), in which at the start the fatty acids and all the other polyols are initially separated from each other.

In other embodiments, polymeric backbones to which fatty acids can be attached and the products used in coating formulations of the present invention which can be radiation cured (by EB/UV) are epoxy resins. The epoxy groups undergo a ring opening reaction with the fatty acids to generate an ester linkage and a second hydroxyl group. The new hydroxyl and any additional hydroxyl group already present in the resin or formed as a result of epoxy cure advancement are available for further fatty acid attachment. These products are identified as epoxy esters and have useful application as metal primers, as well as good exterior durability. Commercial epoxy esters with different oil lengths have been found to be a usefully reactive replacement ingredient in coating formulations of the present invention, and generally perform similarly to the polyester alkyds with similar energy cure characteristics; the epoxy esters require some additional energy to cure while develop greater film hardness.

Polyesters suitable for use in coating formulations of the present invention may be purchased commercially; their properties depend upon the acyl chains and the polyester backbones. Producers of commercial alkyd-backboned polyesters can be found in a directory offered by Thomas Industrial Network, 5 Penn Plaze, New York, N.Y., 1001, which is hereby incorporated in its entirety.

Polyesters suitable for use in coating formulations of the present invention may also be prepared as described below; these preparation processes are illustrative only, and are not meant to be limiting. Such description also serves to further describe and characterize polyesters as defined herein.

Preparation of Polyesters

The sources of the unsaturated fatty acids most directly are natural sources, including but not limited to plant triglycerides and seed storage oils, as described above. These triglycerides may be used directly to yield the side-branched polyesters; in alternative embodiments, fatty acids derived from the triglycerides, such as by reaction with a polyhydric alcohol and a dibasic acid or acid equivalent, are used to form side-branched polyesters. In some embodiments, the plant oil triglycerides themselves are the direct source of the fatty acids as well as the polyol glycerol. Another source of fatty acids is obtained by saponification of triglycerides.

Commonly, conversions involving the triglycerides can be accomplished by two well described processes, the monoglyceride alcoholysis process and the fatty acid or acidolysis process. The alcoholysis process utilizes an initial trans-esterification, most often with glycerol as the polyol, with fatty acid side chain moieties of the triglycerides, subsequently followed by a polyesterification step, or in other words, the addition of the dibasic acid component of the projected polyester and any additional polyol, if needed, to initiate and complete the chain polyesterification conversion. In the acidolysis process, which is primarily utilized with low soluble acids such as isophthalic or especially terephthalic acid, triglyceride and dibasic acid are initially reacted together, subsequently followed by a polyhydric alcohol as may be needed to complete the chain polyesterification.

The dibasic acid components or their reactive equivalent for the alcoholysis and acidolysis (fatty acid) processes include but are not limited to phthalic anhydride, adipic acid, and isophthalic acid.

To augment the polyesterification, a fusion method or solvent azeotropic method may be utilized after the second step of either the alcoholysis or the acidolysis process. In the fusion method, removal of water (a product of polyesterification) can be facilitated by the application of vacuum; however, the unwanted removal of a reactant, such as phthalic anhydride, may also occur. In the azeotropic method, the water produced in the conversion may be further removed by the addition of a small amount (for example, 5% by weight) of an azeotropic solvent, such as xylene. The release of water may be monitored by a Dean Stark receiver, as is well known in the art.

In other embodiments, preparation of the polyesters proceeds via use of fatty acids directly by a fatty acid process. Free fatty acids may be obtained from any source, such as those described above; typical preparation methods include but are not limited to saponification of triglycerides, where preferred sources are plant triglycerides. Saponification may include prior modifications, such as dehydration of castor oil to form dehydrated castor oil (DCO). Tall oil fatty acid (TOFA) is another case of prior modification, which is processing of pine oil. In a fatty acid process, all the ingredients (the polyols, the dibasic acids, the triglycerides, and the fatty acids) are typically added at the start of the reaction. The fatty acid process finds particular utilization for producing polyester chains functionalized with fatty acids when the polyol is other than glycerol.

Monobasic acids such as benzoic acid may also be added to the reaction cook if desired, as for example to control molecular weight developed during polyesterification or to alter or to improve properties as viscosity or water and hydrolysis resistance; exemplary monobasic acids include but are not limited to benzoic acid, and rosin acids and their derivatives. It is contemplated that free hydroxyl groups will be present after whatever method is used to process the cook at its completion, unless under very special conditions (such as a high ratio of fatty acids or other acids, or a very long reaction time). However, coating formulations of the invention do not require that the polyesters retain free hydroxyl groups; thus, these formulations may comprise polyesters with or without free hydroxyl groups.

In some embodiments, fatty acids are obtained from tall oil fatty acids (TOFA), which is one of the more economical sources of fatty acids. TOFA are a distillate byproduct available from pine pulp manufacturing. The fractional distillation separates the fatty acids from secondary products as rosin acids. These fatty acids have a range of proportions of oleic, linoleic and linolenic acid content and are usually obtained from conifers, typically pines, particularly when obtained from European and North America sources. However, the fatty acid composition of the North American source is quite similar to that of commodity soybean oil to which it is often compared in coating applications. TOFA are thus an economically feasible alternative to other plant or seed oils.

Subjecting TOFA to selected treatment, for example, to alkaline hydroxides and elevated temperatures, can result in an isomerization reaction which converts part of the fatty acids to conjugated forms. The presence of conjugated fatty acid side chains does not appear to significantly alter the EB/UV cure activity of any of their resulting polyesters when present in a coating formulation of the present invention, and may in some cases provide some advantages, as is described further below. It is contemplated that more refined higher linoleic acid content TOFA, and its corresponding polyester, will not significantly alter the EB/UV cure response when present in a formulation of the present invention.

TOFA based polyester products are usually associated with non-glycerol polyols and are typically produced by the “all in together” fatty acid process. In contrast, soybean oil polyesters are often generated from the soybean oil triglyceride directly with glycerol as the polyol, typically from the monoglyceride alcoholysis process. These two main production methods are utilized to generate fatty acid pendent polyesters utilized in UV/EB curable coating formulations of the present invention.

In another embodiment, a fatty acid source for fatty acid chain branched polyesters is dehydrated castor oil (DCO). DCO is obtained via a dehydration process of castor oil. The modified triglycerides of DCO typically have a fatty acid distribution with a high proportion of linoleic acid (approximately 60%), as well as significant amounts of a conjugated fatty acid (approximately 20%) which results from the dehydration processing. These fatty acids of DCO triglycerides are used in methods similar to those described above for plant or seed oil triglycerides. The alcoholysis process and polyesterification result in the production of polyesters with radiation energy responsiveness as described herein. Alternatively, saponification of DCO results in free fatty acids, including a conjugated fatty acid. The resulting free fatty acid composition can yield, via the fatty acid process and with a selection of appropriate polyols, a polyester product functionalized with unsaturated fatty acids and conjugated fatty acids, as well as saturated fatty acids, as side group branches. Exemplary appropriate polyols include but are not limited to trimethylolpropane, and an equimolar composition of pentaerythrotol and ethylene glycol. To minimize the possibility of gellation, the mole ratio of dibasic acid to moles of polyol, which is preferably about two moles of dibasic to about three moles of polyol or about 0.66, should be less than about one.

The use of DCO-derived polyester products in a coating formulation of the present invention results in a curing energy requirement similar to the formulation in which polyesters are derived from common commodity soybean oil utilized in the monoglyceride process or produced from free soybean oil fatty acids via the fatty acid process. The radiation cure reaction rate and exotherm, when measured isothermally at ambient temperature using a photocalorimeter, were found to be very similar (within experimental error,) to those for a formulation comprising acrylate/soybean-based polyester and a similarly formulated acrylate/DCO-based polyester. These results are consistent with the existing evidence that the EB/UV cure response is not influenced, at least, to a major degree, by the presence of conjugated of the double bonds in the side groups. It is hypothesized that the slightly improved response to UV/EB treatment observed for a coating formulation comprising DCO-based polyesters compared to a sunflower oil based polyester might in fact be due to the presence of the conjugated fatty acids, although it is not necessary to understand the mechanism of action of the present invention in order to practice it, and the invention is not intended to be limited to any particular mechanism or hypothesis. (See for example, Zeno W. Wicks, Jr., Frank N. Jones and S. Peter Pappas “Organic Coatings: Science and Technology”, 2^{nd} Edition, Wiley-Interscience, New York, N.Y., 1999, p. 265, which recognizes DCO as ‘synthetic conjugated oils’).

Formulations

Currently, the main component of radiation curable coating formulations is an oligomeric acrylate; many formulations further comprise a multifunctional monomer. The oligomeric acrylate may be a single type of oligomeric acrylate or a mixture of more than one type of oligomeric acrylates, while the multifunctional monomer may be a single type of multifunctional monomer or a mixture of more than one multifunctional monomer type. Oligomeric acrylates are available from a variety of commercial entities and include but are not limited to Ebecryl 3720 (a bisphenol A epoxy diacrylate) and Ebecryl 870 (a polyester acrylate), both from UCB Chemicals (now Cytec Surface Specialities, a part of Cytec Industries, Inc., Smyrna, Ga.), and Genomer 3302 available from Rahn AG, Dorflistrasse 120, CH-8050 Zuric). Multifunctional monomers are also commercially available from a variety of producers, such as Sartomer Company (Exton, Pa.). Exemplary multifunctional monomers include but are not limited to glycerolpropoxylated triacrylate (GPTA) and trimethylolpropane triacrylate (TMPTA).

When considering only the acrylates and multifunctional monomers in current coating formulations, the relative proportion of oligomeric acrylate to multifunctional monomer varies widely; typical ranges include from about 100% to about 55% acrylate, with the monomer thus comprising from about 0% to about 45%. Unless specified otherwise, the percentages of coating formulations are expressed on a weight basis.

In coating formulations of the present invention, a portion of the oligomeric acrylate is replaced by polyester. The polyester may be a single of polyester, or a mixture of polyesters. This results in coating formulations with two main components: oligomeric acrylate and polyester. Coating formulations of the present invention may further comprise a multifunctional monomer. Additional components (described further below) may also be present, but these components are typically present in lesser proportions.

When considering oligomeric acrylate alone, up to 50% of the total acrylate in a typical or conventional or current coating formulation is replaced by polyester in a coating formulation of the present invention. The proportion of acrylate which can be replaced depends in part upon the iodine number or value of the polyester; generally, the higher the iodine number of the polyester, the higher the percentage of acrylate that can be replaced by the polyester. Thus, in different embodiments, the proportion of acrylate replaced by polyester is preferably about 15% to about 40%, and more preferably is about 25% to about 35%, and even more preferably is about 20% to about 25%.

Multifunctional monomers promote a high rate of cross-linking due to their polyfunctionality. In a conventional coating formulation, the proportions of oligomeric acrylate and multifunctional monomer may be varied quite substantially, as noted above. In a coating formulation of the present invention, when multifunctional monomer is present, the proportions of oligomeric acrylate, polyester, and multifunctional monomer may also be varied quite substantially. Typical ranges are from about 55% to about 95% for oligomeric acrylate, from about 5% to about 45% for polyester, and from about 5% to about 45% for multifunctional monomer, where the total percentage of these three components is about 100%. Thus, in one embodiment, oligomeric acrylate is present at about 50%, polyester is present at about 20%, and the monomer comprises the remaining about 30%. Other ranges for the proportion of acrylate replaced by polyester are described above. It is a matter of routine experimentation to vary the proportions of these main components to optimize formulation cost and performance, where performance includes both cure rate and energy requirements, and properties of the cured film, such as mar resistance. Guidance for such experimentation is provided is this description, and in particular in the Examples.

Monofunctional monomers may also be present in current radiation curable coating formulations; these monomers may function in a number of different ways, including but not limited to as adhesion promoters, viscosity reducers, and reaction rate improvers. However, they tend to reduce the amount of cross-linking. Such monomers are also referred to as reactive diluents. Exemplary monomers include but are not limited to isobornyl acrylate (IBOA).

Thus, the monomers in a formulation may range from mono- to hexafunctional, and are most commonly mixtures of mono-, di-, and trifunctional acrylates. When present, they generally comprise up to at least about 5 parts (in a 100 part formulation) and may comprise up to about 45 parts. It is contemplated that polyesters may also replace part of the monomers in a radiation curable coating formulation of the present invention; the viscosity of the resulting formulations is preferably optimized or adjusted to fall within industry acceptable ranges, as the viscosity difference between a monomer (with a generally low viscosity) and its polyester replacement (with a generally high viscosity) may be substantial, and the resulting crosslink density of the cured film may be reduced by the presence of the polyester.

Any of the coating formulations of the present invention as described above may further comprise other ingredients, including photoinitiators. Curing under UV generally requires the use of a photoinitiator in the coating formulation; upon exposure to radiation, the photoinitiator leads to the formation of reactive species capable of initiating free radical polymerization. Exemplary photoinitiators include benzoin, benzoin ethers, α,α-dimethoxy-α-phenylacetophenone, diethoxyacetophenone, α-hydroxy-α, α-dimethylacetophenone, 1-benzoylcyclohexanol, and aryl phosphine oxide based photoinitiators such as LUCERIN™, TPO available from BASF Corp. Photoinitiators may be present as a single photoinitiator or as a mixture of more than one. The amounts of photoinitiators when present in coating formulations of the present invention are about the same as those present in conventional UV coating formulations (in which polyester is not present) and are well-known in the art; in some embodiments, these amounts range up to about 10% by weight. Electron beam radiation generates free radical polymerization in the absence of a photoinitiator present in the coating formulation.

Additional optional ingredients of coating formulations of the present invention include wetting agents, flow and leveling agents, fillers, and coloring components, such as any of the pigments or dyes currently used in coating formulations. The amounts of the these additional optional ingredients when present in coating formulations of the present invention are about the same as those present in conventional energy curable coating formulations (in which polyesters is not present) and are well-known in the art. Coating formulations of the present invention without coloring components result in clear coatings or films, while formulations comprising coloring components result in colored or pigmented coatings or films.

Pigment Dispersions

Coloring components, or colorants, are well known in the art, and may be in the form of insoluble finely ground pigments or soluble dyes. Exemplary but non-limiting colorants include diarylide orange, titanium oxide, carbon black, and phthalocyanine green.

Pigment concentrates in alkyd-backboned polyesters are available from several manufacturers, purportedly offering an excellent dispersion, with economy of use and high general compatibility. Until now, these products have often been used as constituents in conventional oxygen mediated curing materials, which include protective coatings and sealants, on wood, plastic, and metal substrates. It is contemplated that these products, if made essentially solvent free, may also be used in formulations of the present invention. These pigmented commercial materials may be introduced directly into a formulation, thus saving a step during production of formulations of the present invention, as the pigment concentrate itself becomes the replacement polyester, or a major part of it. Additional details are provided in Example 8.

Applications

Coating formulations of the present invention are applicable to overprint varnishes (OPV), lithographic inks and metal coatings (clear and pigmented), where the applied coatings are energy cured. Moreover, formulations of the present invention can also be used in screen inks, flexographic inks, wood (furniture and flooring) and plastic coatings, protective coatings, as well as in systems requiring pigment wetting enhancement.

It is also contemplated that coating formulations of the present invention can be used as UV curable adhesive formulations. In these uses, it is contemplated that the cured film acts as an adhesive between two of the same or mixed surfaces or substrates, provided that sufficient radiation energy transparency is available. For example, laboratory microscope slides allow sufficient UV light through to cure many coating formulations of the present invention.

It is also contemplated that coating formulations of the present invention can be used in hot-melt processable powder coatings; in such uses, the formulations comprise non-gelled room temperature solid polyesters (as for example alkyd polyesters or epoxy resins) with a melting range of perhaps about 60° C. to about 120° C.

Thus, coating formulations of the present invention may be applied to a variety of substrates. Exemplary substrates include porous stock such as paper and cardboard, wood and wood products, metals such as aluminum, copper, steel, glass, and plastics such as PVC, polycarbonates, acrylic and the like.

Coating formulations of the present invention may be applied to the substrate or surface and subsequently exposed to a radiation source until an adherent dry polymerized film is formed on the substrate. The formulation is applied by well known methods, including spraying, rollcoating, flexo and gravure processes onto the substrate. The resulting coated substrate is typically cured under a UV or electron beam radiation.

The amount of radiation to cure the coating will depend upon numerous factors, including but not limited to the angle of exposure to the radiation, the thickness of the coating applied, and the amount of polymerizable groups in the coating formulation, as well as the presence or absence of photoinitiators. It is well known in the art that for any particular set of circumstances and factors, routine experimentation is used to determine the amount of radiation to produce a coating of the appropriate properties for a particular coating formulation.

Coating formulations cure at a rate that is monitored on the basis of mar resistance. This measurement, reported as a surface characteristic in milli-Joules per square centimeter (mJ/cm²), represents the energy received from a UV lamp. Reaction exotherms offer an alternative method to assess cure transformations, though the amount of heat generation (the exotherm) does not necessarily reflect either the practical useful mar resistance development criteria, or its corresponding UV lamp amount of input energy (expressed as mJ/cm², for example,) ultimately required, (and which effectively determines cure cost).

Thus, in some experiments, similar results and respective cure rates were observed for coating formulations of the present invention which differed only in the oil length of the polyester component. The different polyesters were all derived from common commodity soybean oil and differed in that they were produced via either the monoglyceride process or from free fatty acids via the fatty acid process; any slight differences observed were due to respective oil lengths, as described above and in Example 1.

In other experiments (described more fully in the Examples below), cure rates for coating formulations of the present invention comprising polyesters derived from different plant oil sources (either DCO, soybean oil, or sunflower oil) were determined by reaction exotherms, which were measured isothermally at ambient temperature using a photocalorimeter. The recorded exotherm energies in these experiments were based upon the weight of the applied formulations and are reported in Joules/gram (J/g). Each formulation in these experiments contained 15% by weight of polyester and 3.5% by weight of Daracur 1173 (CIBA), a photoinitiator. The cure exotherms for all three types of formulations were found to be very similar. In fact, the results observed for one pair of formulations, those comprising acrylate oligomer/soybean oil derived polyester and a similarly formulated acrylate oligomer/DCO derived polyester, were essentially the same within experimental error.

Thus, a comparison of formulations comprising polyester derived from DCO 2477 (a commercially sourced about 40 to about 45 oil length product from Reichhold, Raleigh, N.C.), and a similar formulation comprising polyester derived from soy product 5070 (a commercially available about 62 oil length non solvent containing product from McWhorter of Carpentersville, Ill.) resulted in equivalent cure exotherms for both formulations (within nominal experiment error) of about 165 J/g. A similar formulation comprising polyester derived from sunflower oil (EPS 6644, about 72% oil length, EPS Color Corp. of Am., Marengo Ill.) yielded a slightly lower exotherm of about 155 J/g. Additional data from formulations comprising oligomeric acrylates only, such as similar oligomeric polyesterdiacrylates identified from UCB Chemical (now Cytec Solution Specialties), Ebecryl 870, and from AkzoNobel, Actilane 540 (both with Daracur 1173 (CIBA) 3.5%), yielded an exotherm of about 200 J/g.

These results support the hypothesis that the UV/EB curing response mechanism is not the same as conventional oxygen mediated response mechanism (described further below). They also demonstrate that formulations of the present invention comprising different polyesters result in similar cure responses. Furthermore, it is contemplated that the exotherm measurement provides a useful cure characterization, which is believed to be related to the free radical potential response of the various polyesters used in coating formulations of the present invention.

Fourier Transformation Infrared Spectroscopy (FTIR) data has shown, with the diminishment of the acrylate double bond at 810 cm⁻¹ and the diminishment of the cis C—H stretch double bond peak at 3008 cm⁻¹, that double bond polymerization and crosslinking polymerization has occurred. However, complete diminishment of the peak does not occur. Therefore, some double bonds remain unreacted, up to about 20-30% as estimated from peak heights; these results are expected, since viscosity build-up essentially confines movement of the isolated double bonds away from a molecular reaction center.

Other applications exist in the field of nanotechnology, where the improved pigment wetting and dispersion associated with coating formulations of the present invention are contemplated to be especially useful. For example, UV/EB coating formulations of the present invention comprising nanoparticles are contemplated to have utility when applied to green chemistry, improved scratch and abrasion resistance coatings, UV inkjet inks, and waterproofing seals. For inkjet inks, a low viscosity formulation is preferred.

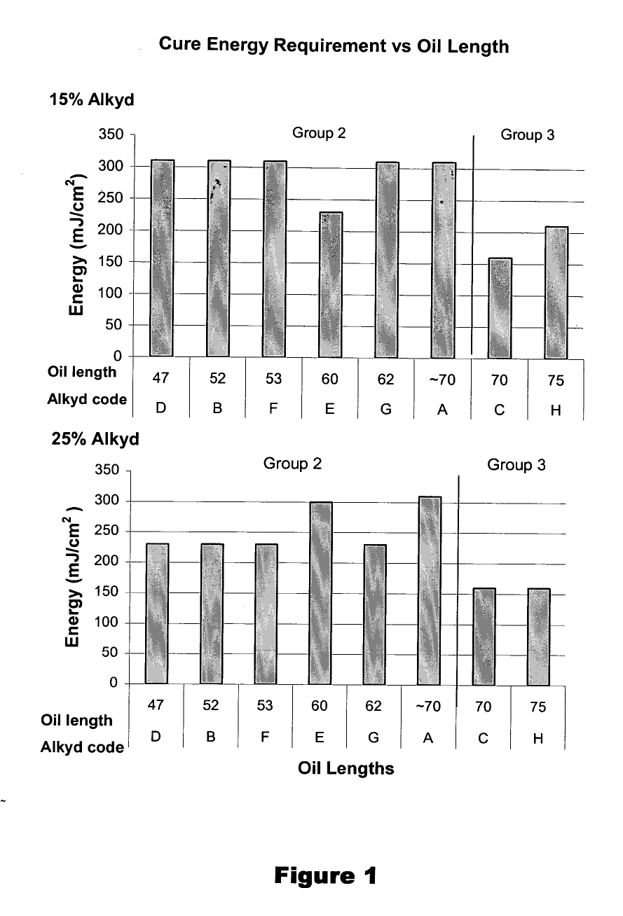

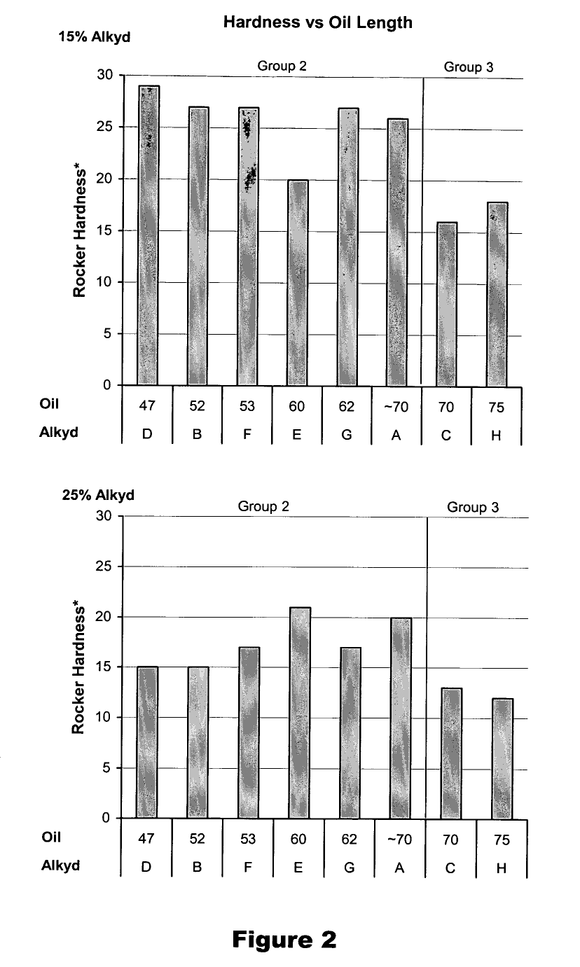

Moreover, coating formulations of the present invention which do not comprise either mutlifunctional or monfunctional monomers may be especially useful when applied to substrates composed of porous medium, as is demonstrated in the Examples (especially Example 1 and FIGS. 1 and 2). It is anticipated that these formulations will result in less bleeding and result in reduced exposure to any remnant uncured acrylates, which is undesirable for health reasons. The absence of multifunctional monomers in coating formulations of the present invention is also anticipated to reduce dot gain.

Advantages

Formulations of the present invention, in which polyesters with fatty acid pendent chains replace a portion of the acrylic oligomer in a typical coating formulation, including but not limited to metal, wood or plastic coatings, and overprint coatings, provide an economic advantage because the polyesters with fatty acid chains are less expensive than acrylic oligomers. Moreover, the efficiency of the pigment dispersion and its associated manufacturing step will be substantively improved in pigmented systems, due to an increase rate of effecting pigment wetting and dispersion. This improved efficiency is of particular importance in the manufacture of printing ink, as printing ink generally requires finer particle sizes then the paint industry, or in other words, a lower Grindometer reading then is required in a paint application. Thus, as described herein, the presence of polyester in an acrylate oligomer energy curable formulation at a cost effective level results not only in UV/EB cure capability, but also results in sufficient reactivity to be effective in UV based commercial print or paint curing, in many cases with no loss in cure rate compared to the non-polyester competitive formulations, and in a number of cases will achieve a cure rate enhancement, based on the accepted mar resistance/thumb twist profile.

A film obtained from a formulation of the present invention and cured to a satisfactory mar resistance/thumb twist level for a printing application may be somewhat softer and its chemical resistance (methyl ethyl ketone (MEK) swab pats) may be slightly diminished; however, in other respects, its performance is generally equivalent to those of present commercially available EB/UV ink formulations. A thicker UV/EB film, either pigmented or non-pigmented, prepared from a coating formulation of the present invention with perhaps a slight increase in energy cost, can be competitive with a nominally thicker pigmented or non-pigmented UV/EB curable film prepared from currently available coating formulations; preferable formulations of the present invention comprise isophthalic polyesters with their reported greater solvent resistance, or epoxy polyesters with their reported greater exterior durability. A non-limiting example includes powder coatings.

In contrast to typical commercial UV/EB formulations containing acrylate oligomeric resins, coating formulations of the present invention comprising polyesters as partial replacement of oligomeric acrylates may also provide improved pigment wetting and dispersion processing. Preferred polyesters are chain polyesters containing fatty acid side branches which are essentially solvent free; these include commercially available products derived from either a conventional polyester and formulated to contain solvent that is during its conversion process pre-extracted prior to addition to solvent, or where the solvent is minimal as in the azeotrope process, or where the solvent is stripped from the commercial polyester, and the commercially available polyesters which are produced without a solvent. Thus, the pigment dispersion medium that contains the acrylate resin, the fatty acid chain branched polyester, a polyfunctional monomer and optionally a photoinitiator, can yield a uniform highly dispersed pigment medium, beneficially applicable to the energy curing of pigmented coatings.

Another advantage is that a formulation of the present invention, as either pigmented or clear, serves to effectively decrease the mentioned often-oppressive acrylate odors, and to diminish to a useful degree any potential deleterious effects on health.

Although it is not necessary to understand the mechanism to practice the present invention, and the invention is not intended to be limited to any particular mechanism, it is hypothesized that the process of curing coating formulations of the present invention by EB/UV differs from that of conventional air drying paints and conventional lithography and letterpress printing inks. In formulations of the present invention, the polyester components of the formulations are often identified as an oxidizing type. These oxidizing polyesters can be characterized as previously described (Zeno W. Wicks, Jr., Frank N. Jones and S. Peter Pappas, 2^{nd} Edition, Op. Cit., p. 268), in that the polyesters have the ability to undergo a complex auto-oxidation cross-linking process mediated by oxygen. The drying and semidrying triglyceride plant oils described by Wicks et al. (Ibid. p. 258, 260) serve as the initial ingredients in the production of these polyesters. The authors describe two main processes to produce these alkyds, which are the processes described previously. The first process is the monoglyceride process (Ibid. p. 270, 278), a form of the alcoholysis process in which glycerol is the polyol. All other polyols and their combinations are generally produced by the second process, the fatty acid process, (Ibid., p. 278), in which the fatty acid side chains are the result of the initial saponification of a triglyceride

Thus, some of the fatty acid side chains in polyester components of formulations of the present invention are also the active moieties in air-drying paints and air-drying lithography and letterpress printing inks, where the air-drying is an oxidative process. These generic alkyds of air-drying paints and inks are identified as being among the oxidizing alkyds as described above. The air-drying oxidation process (see for example “The Printing Manual,” 4^{th} Ed., Ed. By R. H. Leach, C. Armstrong, J. F. Brown, M. J. Mackenzie, L. Randall, and H. G. Smith, Van Nostrand Reinhold Co. Berkshire, England, 1988, p. 331) is applicable to paint coatings and commercial inks that cure (or dry) under exposure to air; this is referred to as conventional alkyd air drying process. However, the curing or drying of the paint coatings and commercial inks occurs at a much slower rate then the rate necessary for the EB/UV curing process. The former is triggered by oxygen and adds oxygen to its structure, and often includes the formation of conjugated structures as intermediates. In contrast, during the energy curing process (UV/EB) of coating formulations of the present invention, the presence of oxygen is undesirable and is therefore minimized, and conjugation is not produced or found (as verified by NMR), unless originally present (as, for example, in the case of the dehydrated castor oil polyesters). The reactivity as occurs in the oxidative crosslinking polymerization is thus believed to be different from, and not of the same reactive order, as that when energy curable process is applied to the identical polyesters when present in the coating formulations of the present invention. Therefore, the main steps of the conventional alkyd air-drying process are not the same as the main steps involved in the polymerization and/or copolymerization crosslinking process of an acrylate/polyester coating formulation of the present invention during UV/EB-curing, even though both processes involve free radicals.

### EXAMPLES

These and other aspects of the present invention can be deduced by those skilled in the art to which it pertains by reference to the preceding description and the following Examples. The following Examples are thus provided for purposes of clarity in order to more fully describe and demonstrate the methods by which coating formulations of the present invention may be prepared, used, and characterized, resulting in novel high crosslink density coatings of the present invention. Although polyesters of the coating formulations of the present invention are commercially available, examples are also provided as to how these polyesters may be prepared. However, these Examples are not meant to be limiting in any manner, and modifications and adaptations may be made to provide other routes or end products, all of which are to be considered to be within the scope of the present invention.

Examples 1-5 describe exemplary coating formulations of the present invention; Example 6 describes commercial fatty acid process products, and their formulation and use in coating formulations of the present invention. Examples 7-8 describe an application of the present invention to pigmented and ink formulations.

### Abbreviations

In the Examples, the following abbreviations are used:

ASTM (??); DCO (dehydrated castor oil); EB (electron beam); EG (ethylene glycol); FTIR (Fourier Transformation Infrared Spectroscopy); J/g (Joules/gram); mJ/cm² (milliJoules/cemtimeter squared); MEK (methyl ethyl ketone); OPV (overprint varnishes); PE (pentaerythritol); PG (propylene glycol); TMP (1,1,1-trimethylolpropane); TMPTA (trimethylolpropane triacrylate); TOFA (tall oil fatty acids); TRPGDA (tripropyleneglycol diacrylate); UV (ultraviolet).

### Example 1

### Effect of Alkyd Oil Length on Film Cure Energy Requirement and Hardness

The practical cure measurement of coatings of this invention has been mar resistance and/or thumb twist testing, as is well known in the art. While it is not necessary to understand the mechanism of the present invention, and the invention is not intended to be limited to any particular hypothesis, it is hypothesized that these practical tests reflect two major properties of the films: Film crosslink density and film stiffness. It is further hypothesized that these two properties have an inverse relationship to each other. Film crosslink density is a function of the number of unsaturated fatty acid chains available in the coating formulation, and is increased as the number of fatty acids introduced along a polyester chain is increased, in a coating formulation of the present invention in which the proportion of oligomeric acrylate is constant. Thus, the greater the oil length number of the polyester, the greater the number of unsaturated fatty acids, and the greater the resulting crosslink density. On the other hand, stiffness of the polymer is a function of the number of aromatic groups and the oxygen content in each molecule of polyester of a coating formulation of the present invention. Aromatic groups are stiffer, and oxygen groups are more polar, than aliphatic pendent chains. As the oil length number increases, the percentage of the stiffer aromatic groups and oxygen functionalities decreases, resulting in decreased film stiffness.

A test to examine the hypothesis proposed above was undertaken by using a two component system, or in other words a coating formulation comprising oligomeric acrylate and polyester but no (polyfunctional) monomer. This test series thus simplifies coating curing kinetics for experimental purposes.

The coating formulations comprised the oligomeric acrylate (Ebecryl 870, obtained from UCB, now Cytec Surface Specialities) and polyester, with the weight proportions of these two components when considered alone equaling 100%, plus 4% initiator (Darocur 1173). The identification code and properties of the functionalized chain polyesters is shown in Table 1. The formulations did not comprise any monomers. #3 Wire wound drawdowns were used to prepare coatings on glass. Cure value was determined at the initial point of achieving mar resistance, or in other words, no mark was observed upon application of a wooden tongue depressor. Hardness was determined by the Sward Hardness test (ASTM 2134).

TABLE 1
Identification and Characteristics of Various Polyesters
in the Simplified Two Component Test System

| Polyester | | | | | |
|---|---|---|---|---|---|
| Code/ | | | | | |
| Product # | Producer | Oil length | Mₙ | M_{w} | Comment |
| A | OPC Polymers | ˜70 | | | |
| 7454-M-70 | Cleveland, OH | | | | |
| B | CCP Polymers | 52 | | | |
| 802-1005 | Kansas City, MO | | | | |
| C | AKZO-Nobel | 70 | | | Pentaerithritol, |
| 1317 | Matteson, IL | | | | Terephthalic |
| | | | | | acid based |
| D | McWhorter | 47 | ˜2400 | Highly | |
| 51-5135 | (Eastman), | | | Polydisperse | |
| | Carpentersville, IL | | | | |
| E | Same as above | 60 | 16,000 | Polydispersity | |
| 201-2092 | | | | 9.4 | |
| F | ″ | 53 | 246,000 | Polydispersity | |
| 204-1624 | | | | 74 | |
| G | ″ | 62 | ˜2400 | Moderately | |
| 50-5070 | | | | polydisperse | |
| H | AKZO-Nobel | 75 | | | Trimethylol |
| 1008 | Matteson, IL | | | | propane, |
| | | | | | Isophthalic |
| | | | | | acid based |

The test series was first utilized to investigate coating cure energy requirement versus oil length; the results are presented in FIG. 1. The results support the hypothesis that crosslink density and film stiffness are major factors underlying cure energy requirements, or in other words, to obtaining acceptable mar resistance/thumb twist test results. These factors, which both depend on the polyester oil length, tend to work in opposite directions. Long oil polyesters (those with a higher proportion of fatty acid side chains) develop a greater crosslink density, but produce a softer film. Polyesters with reduced oil lengths (those with a lower proportion of fatty acid side chains) develop a lower crosslink density but produce stiffer films (more aromatic groups).

The results shown in FIG. 1 also suggest that coating formulations may be divided into three groups. In Group 1, the coating formulation comprises no polyester. This group (which is not shown in FIG. 1) requires about 310 mJ/cm² to cure. Group 1 films also have good solvent resistance, which is slightly greater than those of the films in Groups 2 and 3.

In Group 2, the coating formulations comprise oligomeric acrylate and polyester; in this group, the polyester oil lengths are between about 45% and about 70%. When the proportion of polyester is about 15%, the curing energy requirements are about the same as those films of Group 1, about 310 mJ/cm², (with one group member, sample polyester E, requiring less energy of about 225 mJ/cm²). These coating formulations possess uniformity of curing energy requirements, which uniformity indicates that the crosslink density/stiffness factors tend to balance out. When the proportion of polyester is about 25%, the cure rate of the films is faster than those observed for films of Group 1. This reduction in cure energy requirements (except for Polyester E), is consistent with what is known about copolymerization chemistry and reactivity ratios, particularly as applied to two component system (or in other words, one in which no monomer is present; see for example C. Hagiopol, “Copolymerization: Toward a Systematic Approach”, Kluwer Academic/Plenum Publishers, New York, 1999). In the coating formulations of Group 2, the first component, the oligomeric acrylate is a hexafunctional system, as specified by the manufacturer, and the second component, the polyester, is also a multifunctional system.

The coating formulations of Group 3 comprise oligomeric acrylate and polyester with oil lengths of about 70 or greater; in this group, the crosslink factor dominates. Moreover, for the films obtained from coating formulations with a proportion of polyesters at about 15% and at about 25%, the cure energy requirement is only about two thirds the energy requirements of Group 2 films; this result is also consistent with the most probable reactivity ratios and associated copolymerization chemistry described above.

This consistency (with the one exception noted above) is particularly noteworthy in view of the wide variety of polyesters available. It is contemplated that variations in molecular weights of a single polyester, as determined by number average (Mₙ) and/or weight average (M_{w}), will be a factor in the curability of a film in which the polyester is a component. For example, an increase in polyester M_{w} can substantially increase the viscosity, which may have a large effect on the reaction rates. Generally, as observed, some threshold value of polyester Mₙ (typically about 1000) should be achieved before comparisons can be made, or more generally, the polyester preferably comprises at least about two polyols and two dibasic acids before making comparisons.

The test series was next utilized to investigate coating hardness versus oil length. Hardness was measured by the Sward Harness Rocker following ASTM 2134, and the results are presented in FIG. 2. Assuming that the Sward Hardness of the cured films is an indication of or correlated to the stiffness of the film, the results shown in FIG. 2 are consistent with the curability data as shown in FIG. 1. Thus, the films of Group 2 are harder then the films of Group 3, at both at the 15% and 25% polyester level. The hardness values are numerically on average about 40-50% higher for Group 2 films when compared to Group 3 films, and this correlation is believed to extend generally to most polyesters. It is contemplated that slight variation in the degree of hardness observed in each group will result from variations in different polyesters, such as different molecular weights, as well as due to the presence of different ingredients in different films. The hardness value for the films of Group 1, which comprise from none to possibly a small amount of polyester, is higher than about 43 rocks. Clean glass has a hardness of about 50 rocks.

Thus, the results shown in FIGS. 1 and 2 demonstrate that film curing energy requirements are inversely related to film hardness. These results also demonstrate that coating formulations comprising polyester, with either a long oil length or a medium oil length, are able to replace up to about 25 weight % of an acrylic resin in a comparative control formulation, with enhanced curability as determined by mar resistance/thumb twist energy requirements. The polyesters of the formulations for which results are shown in FIGS. 1 and 2 represent both long oil and medium oil lengths. (Although there is no consensus of an exact definition of where the long oil length category begins and the adjacent medium oil length category ends, an oil length of about 60 is considered the dividing line by some.) As described above, the calculated oil length number is a more precisely defining parameter than the general denomination as long oil or medium oil.

### Example 2

### Effect of Polyesters in Clear Film Formulations on UV Curing

The effects on UV curing of partially substituting polyesters obtained from soybean based products for oligomer acrylate in film formulations was examined. The films comprised a medium oil or a long oil polyester, where both polyesters were soybean oil based products; the results are shown in Table 2. Up to 33% of the acrylate oligomeric resin was replaced by the polyesters, resulting in a reduction in curing energy requirement over that of the control formulation.

TABLE 2
UV Curing of Clear Film Formulations Show Enhanced Cure Rates
with Selected Polyesters in Partial Substitution for the Oligomer Acrylate
(#3 wirewound draw-downs on glass)

| | | Energy | | |
|---|---|---|---|---|
| | Film | (mJ/cm²)¹ | Sward | |
| | Thickness | Tack Free | Hardness | MEK |
| Formulations | (μm) | Cure | Rocker | Resistance |
| Control Formulation | 9 | 500 | 49 | no |
| 0% soy polyester/ | | | | swell |
| 75% polyesteracrylate²/ | | | | |
| 20% TRPGDA³/ | | | | |
| 5% photoinitiator⁴ | | | | |
| 15% long oil soy | 10 | 330 | 32 | swell |
| polyester⁵/ | | | | |
| 60% polyesteracrylate²/ | | | | |
| 20% TRPGDA³/ | | | | |
| 5% photoinitiator⁴ | | | | |
| 25% long oil soy | 11 | 330 | 27 | swell |
| polyester⁵/ | | | | |
| 50% polyesteracrylate²/ | | | | |
| 20% TRPGDA³/ | | | | |
| 5% photoinitiator⁴ | | | | |
| !5% medium oil soy | 12 | 330 | 33 | swell |
| polyester⁶/ | | | | |
| 60% polyesteracrylate²/ | | | | |
| 20% TRPGDA³/ | | | | |
| 5% photoinitiator⁴ | | | | |
| 25% medium oil soy | | | | |
| polyester⁶/ | | | | |
| 50% polyesteracrylate²/ | 14 | 330 | 25 | swell |
| 20% TRPGDA³/ | | | | |
| 5% photoinitiator⁴ | | | | |

¹The recorded energy data are based on a radiometer determination, UVmap plus EIT, Inc., Sterling, VA obtained on the UV setup that utilizes a 3Ø Fusion/Aetek UV Curing System with an H lamp configured with a variable speed conveyer belt. At the high lamp setting of the high lamp setting (400 watts) of this data the peak intensity UVA (220-290 nm) was 5.9 watts/cm². The thumb twist and the tongue depressor mar resistance test were applied.
²UCB Chemical, Smyrna, GA, RadCure Products - Ebecryl 870 (now Cytec Surface Specialities)
³Tripropylene glycol diacrylate
⁴Irgacure 500 (CIBA)
⁵7454-M-70, Ohio Polychem, part of OPC Polymers, Columbus, OH
⁶#802-1005, Penninsula Polymers, part of CCP, Kansas City, MO

### Example 3

### Comparison of a Drying Oil and a Semidrying Oil

Properties of coating formulations of the present invention comprising a ‘drying oil’ or a ‘semidrying oil’ were compared. These exemplary formulations comprised a linseed oil polyester, which is a fatty acid side group functionalized polyester and is designated a ‘drying oil’ polyester, and a soybean oil polyester, which is a fatty acid side group functionalized polyester and is designated a ‘semidrying oil’ polyester. These are practical distinctions, ultimately based on the fact that linseed oil offers a faster air dry and has some 5-6 times the amount of linolenic, and thus about 35 percent more unsaturation, then commodity soybean oil.

The resulting cure energy requirements, and film hardness and resistance for the two exemplary formulations and a control or comparative example containing no polyester are shown in Table 3a. These results support the proposed mechanism, as described earlier, that the conventional oxygen mediated curing mechanism of the generic polyesters does not play any significant role in the energy (UV/EB) curing of the same polyesters, and that the conventional designations of ‘drying oil’ and ‘semidrying oil’ are not applicable to the formulations of the present invention. Thus, the higher amount of cure energy required for the ‘drying oil’ as compared to the ‘semidrying oil’ is inconsistent with the current characterization of increased reactivity of ‘drying oil’ such as of linseed oil products.

TABLE 3a
Soybean and Linseed Oil Polyesters in UV-Curable Clear Coat Application
(#3 wirewound draw-downs on glass)

| | | | | Energy | Sward | MEK |
|---|---|---|---|---|---|---|
| | | | | (mJ/fcm²)³ | Hardness | Resistance |
| | | Polyester | | Tack | New | New |
| Long Oil | | Visc.² | | Free | *** | *** |
| Polyester | Source¹ | (Poise) | Formulation | Cure | Aged | Aged |
| Soybean | Peninsula | 35 | 15% polyester/ | 250 | 9 | Swell |
| oil based | Polymer | | 30% fatty acid epoxydiacrylate⁴/ | | *** | *** |
| | #801-5002 | | 30% bisphenol A epoxydiacrylate/ | | 19 | Swell |
| Linseed | Ohio | 14 | 20% TMPTA⁵/ | 500 | 8 | Swell |
| Oil based | Polychem | | 5% photoinitiator⁶ | | *** | *** |
| | #6502 | | | | 19 | Swell |

| | | | | |
|---|---|---|---|---|
| Comparative Example | 37.5% fatty acid expoxydiacrylate⁴/ | 200 | 49 | No swell |
| (Formulation contains no | 37.5% bisphenol A diacrylate/ | | *** | *** |
| polyester) | 20% TMPTA⁵/ | | | |
| | 5% photoinitiator⁶ | | | |

¹Peninsula Polymers is part of CCP, Kansas City, MO; Ohio Polychem is part of OPC Polymers, Columbus, OH
²Laray Falling Rod Viscometer at 25° C. and 2500 sec⁻¹
³Calculated from passes at 100 fpm required to achieve a tack free state and the comparative energy output measurement of the 200 watt/in Hanovia H lamp utilized in the particular UV setup. The non-soy required 1 pass, while the long oil soy formulation required 2 passes at 100 fpm and the lower viscosity linseed oil required 3 passes. The thumb twist tack free test is applied.
⁴UCB Chemical, Smyrna, GA, Radcure Product Ebecryl 3702 (now Cytec Surface Specialities)
⁵Trimethylolpropane triacrylate
⁶Irgacure 500 (Ciba)

The resulting cure energy requirements, and film thickness, hardness, and resistance for exemplary formulations in which the amount of a soy polyester or a linseed oil polyester varied, and a basic control formulation containing no polyester, are shown in Table 3b. These results provide additional evidence of the similar reactivity in UV/EB processing of a linseed oil polyester and a soybean oil polyester, with the energy requirements being essentially identical and the same as the control formulation. Both oils are of the same oil length category and the same viscosity range. The soybean oil polyester formulation and the linseed oil polyester formulation require the same energy to cure and achieve essentially the same hardness at the same designated cure point. They can both replace up to at least about 33% of acrylate oligomer, also without effecting the cure energy requirement.

TABLE 3b
Comparable Soybean and Linseed Oil Polyesters, Present in Variable Amounts,
in UV-Curable Formulations. The Effect on Cure Energy Requirements,
Hardness and MEK Resistance
(Polyesters Replace up to 33% of the Acrylate Oligomer Resin)
(#3 wirewound drawdowns on glass)

| | | | Energy | | | |
|---|---|---|---|---|---|---|
| | | | (mJ/cm²) | Film | | |
| Polyesters | PolyEster | | Tack Free | Thickness | | MEK |
| (Source) | Visc.¹ | Formulation | Cure | (μm) | Hardness | Resistance |
| No Polyester | 18 | 75% polyesterhexaacrylate³/ | 500 | 9 | 49 | No |
| (Basic Control | | 20% TRIPGDA⁴ | | | | Swell |
| Formulation) | | 5% Photoinitiator⁵ | | | | |
| Soy polyester long | ″ | 15% soy polyester/ | 500 | 10 | 41 | Swell |
| oil, phthalic acid | | 60% polyesterhexaacrylate³/ | | | | |
| Based | | 20% TRPGDA^{4/} | | | | |
| (Reichhold Aroplaz | | 5% photoiniator⁵ | | | | |
| 1272) | | | | | | |
| Same as above | ″ | 25% soy polyester | 500 | 7 | 30 | Swell |
| (Same as above) | | 50% polyesterhexaacrylate³/ | | | | |
| | | 20% TRPGDA^{4/} | | | | |
| | | 5% Photointiator⁵ | | | | |
| Linseed oil | ″ | 15% linseed polyester | 500 | 9 | 33 | Swell |
| polyester, long oil, | | 60% polyesterhexaacrylate³ | | | | |
| phthalic acid based | | 20% TRPGDA⁴ | | | | |
| (Reichhold Aroplaz | | 5% Photointiator⁵ | | | | |
| 1271, the linseed oil | | | | | | |
| version of Aroplaz | | | | | | |
| 1272) | | | | | | |
| Same as above | ″ | 25% linseed polyester | 500 | 7 | 29 | Swell |
| (Same as above) | | 50% polyesterhexaacrylate³ | | | | |
| | | 20% TRPGDA⁴ | | | | |
| | | 5% Photointiator⁵ | | | | |

¹See Table 3a, second footnote
²Energy data were determined on the UV setup that utilizes a 3Ø Fusion/AETEK, Romeoville, IL curing with an H lamp and fitted with a variable speed conveyor belt. The system operated at the high lamp setting (400 watts). The UVA peak intensity, 220-290 nm, is 5.900 watts/cm² (UV map plus, EIT, Inc., Sterling, VA. Cure judged by lack of thumb twist and tongue depressor non surface marring.
³UCB Chemical, Smyrna, GA, Radcure Products - Ebecryl 870 (now Cytec Surface Specialities)
⁴Tripropyleneglycerol diacrylate
⁵Irgacure 500, CIBA

The results for UV curing of the coating formulations of the present invention in which the polyester products are obtained from different manufacturers are shown in Table 3c. Three different formulations were evaluated. Formulation A comprised polyesters of medium oil length or long oil length with a mix of viscosities, and a photoinitiator present at a level common to non-pigmented formulations; Formulation B comprised polyesters of long oil length and different viscosities, and a photoinitiator present at the same level as in Formulation A; and Formulation C comprised a polyester of long oil length and a photoinitiator present in a higher lever more common to a pigment containing formulation. Each series of formulations was also compared with a formulation without any alkyd polyester present, which served as a control. These comparisons allowed an evaluation of the effect of different polyesters of similar oil length within a single formulation, as well as a comparison of the effect of medium oil length with long oil length polyester, the effect of different viscosities, and the effect of lower versus higher photoinitiator, on UV curing.

Coating formulations comprising medium oil length polyester (Formulation A) from different sources differ substantially in viscosity but are remarkably similar to each other and to their comparative no-polyester control formulation in both energy cure and film hardness. In particular, the polyesters from either McWhorter or Ohio Polychem respond similarly to UV cure, requiring essentially the same cure energy, and provide very acceptable cured films. These results are consistent with the concept that although the molecular weight of medium oil length polyester (and in particular of non-gelled alkyd-polyesters) may vary, if it meets a threshold of at or above about 1,000, the effects on cure energy requirements will be minimal. In contrast, these two formulations require more cure energy than do formulations comprising the long oil product Degen 4632, which is also very viscous.

Formulation B comprises long oil length polyester with either a very high viscosity or a moderate viscosity. These particular formulations result in films that have a lower energy cure requirement and have approximately one-half the Sward-Hardness of the films formed by Formulation A comprising medium length polyester (as described above). The low swell or no swell of the Degen isophthalic polyesters (in Formulations B and C series) is believed to be significant, and may reflect greater crosslink density resulting from their long oil length and relative greater double bond concentration.

Formulation C, which comprises higher levels of photoinitiator, results in a substantially decreased cure rates both when polyester is present and when it is not. These results underscore the importance of the concentration of photoinitiators on cure kinetics.

TABLE 3c
UV Curing of Coating Formulations Comprising Soybean Oil Based Polyester
from Several Manufacturers
(#3 wirewound Drawdowns on Glass)
(Cure - mar resistance/thumb twist)

| | | | | | |
|---|---|---|---|---|---|
| | | ‘Neat’¹ | | | |
| | | Polyester | Energy | | |
| | Polyester | Visc.² | Cure | Sward | MEK |
| Manufacturer | Description | (Poise) | (mJ/cm²)³ | Hardness | Resistance |

Formulation A (selected formulation) 15% polyester/60% polyesteracrylate⁴/
20% TRPGDA⁵/5% Photoinitiator⁶

| | | | | | |
|---|---|---|---|---|---|
| Ohio Polychem⁷ | 6766 medium oil length | ˜1000 | 500 | 41 | Swell |
| Columbus, OH | (kettle solids) | | | | |
| McWhorter | 55-5501 medium oil | ˜35 | 500 | 37 | Swell |
| Technologies | length | | | | |
| Carpentersville, IL | | | | | |
| Degen Oil & | 4632 isophthalic acid | 590 | 300 | 27 | Slight |
| Chemical Co. | long oil length | | | | swell |
| Jersey City, NJ | | | | | |

| | | | |
|---|---|---|---|
| Formulation A, but no polyester. 75% polyesteracrylate⁴/20% | 500 | 49 | No swell |
| TRPGDA⁵/5% Photoinitiator⁶ | | | |

Formulation B (selected formulation) 15% soy polyester/12% Bisphenol A
epoxydiacrylate⁸/48% polyesteracrylate⁴/20% TMPTA⁹/5% Photoinitiator⁶

| | | | | | |
|---|---|---|---|---|---|
| Degen Oil & | 4633 isophthalic acid, | 45 | 400 | 16 | Slight |
| Chemical Co. | long oil length | | | | swell |
| Jersey City, NJ | | | | | |
| Degen Oil & | 4632 isophthalic acid, | 590 | 300 | 19 | No swell |
| Chemical Co. | long oil length | | | | |
| Jersey City, NJ | | | | | |

| | | | |
|---|---|---|---|
| Formulation B, but no polyester. 15% Bisphenol A | 300 | 47 | No swell |
| epoxydiacrylate⁸/60% polyesteracrylate⁴/ | | | |
| 20% TMPTA⁹/5% Photoinitiator⁶ | | | |

Formulation C (selected formulation) 18.3% polyester/10.6% Bisphenol A
epoxydiacrylate⁸/42.2% polyesteracrylate⁴/16.7% propoxylated
glyceroltriacrylate/12.2% Photoinitiator pkg¹⁰.

| | | | | | |
|---|---|---|---|---|---|
| Degen | 4632, as above | As above | 160 | 30 | Swell |

| | | | |
|---|---|---|---|
| Formulation C, but no polyester. 13.5% Bisphenol A | 70 | 36 | No Swell |
| epoxydiacrylate⁸/ | | | |
| 54.8% polyesteracrylate⁴/19.5% propoxylated glyceroltriacrylate/ | | | |
| 12.2% Photoinitiator pkg.¹⁰ | | | |

¹“Neat” polyesters contain no additives or essentially no solvents.
²Laray Falling Rod Viscometer at 25° C. and 2500 sec⁻¹
³Utilized Fusion AETEK H lamp (200 Watts/in) 2.776 watts/cm² based on a thumb twist tack free state
⁴UCB Chemical Ebecryl 870 (now Cytec Surface Specialities)
⁵Tripropyleneglycerol diacrylate
⁶Irgacure 500 (CIBA)
⁷Ohio Polychem, part of OPC Polymers, Columbus, OH.
⁸UCB Chemical Ebecryl 3720.
⁹Trimethylol propane triacrylate
¹⁰Proprietary

### Example 4

### Effect of Varying Amounts of Polyester on Cure Kinetics

The effect of varying amounts of an polyester on cure kinetics was examined using a proprietary, non-commercial soybean polyester (from McWhorter); the results are shown in Table 4. These results indicate that when the polyester replaces 15% of the acrylate, the energy of cure is about 60% required by the control formulation, but when the polyester replaces 25% of the acrylate, the cure energy was about the same as that of the control formulation. Thus, cure kinetics are optimally determined for each coating formulation of the present invention.

TABLE 4
UV Curing of Clear Films Containing Variable Amounts of a Selected
Commercial Soybean Polyester
(#3 wirewound drawdowns on glass)

| | Energy | | |
|---|---|---|---|
| | Tack Free | Sward | |
| | Cure | Hardness | MEK |
| Formulations | (mJ/cm²)² | Rocker | Resistance |
| 0% soy polyester/75% | 500 | 49 | no |
| polyesteracrylate/20% TRPGDA³/ | | | swell |
| 5% photoinitiator⁴ | | | |
| 15% soy polyester/60% | 290 | 37 | swell |
| polyesteracrylate/20% TRPGDA/ | | | |
| 5% photoinitiator | | | |
| 25% soy polyester/50% | 500 | 30 | swell |
| polyesteracrylate/20% TRPGDA/ | | | |
| 5% photoinitiator | | | |

¹‘Neat’ proprietary soybean polyester, medium oil length, high viscosity, McWhorter Technologies, Carpentersville, IL, contains ˜2% xylene.
²The recorded energy data were radiometrically obtained on the UV setup that utilizes a 3Ø Fusion/AETEK UV Curing System with an H lamp attached to a variable speed-conveying belt. The lamp was at the low setting of 200 watts and the peak intensity, UVA (220-290 nm), was 2.776 watts/cm². The thumb twist tack free test was applied.
³Tripropylene glycol diacrylate
⁴Irgacure 500 (CIBA)

The results described in Examples 1-4 demonstrate the use of the polyesters in formulations for clear coatings. While the cured films containing the generic alkyd-polyester formulation product are somewhat softer then in its non-alkyd-polyester counterpart formulation, there is, depending on the formulation, often little sacrifice in cure rate, and at times an enhanced cure rate, all with little change in film performance.

### Example 5

### Use of Formulations Comprising Polyesters in Lithography

The utility of coating formulations comprising polyesters for lithography printing was examined with a soy polyester in UV ink formulations and using the formulations for printing on quality-coated paper for lithography. The results for final ink formulations are summarized in Tables 5a and 5b. When inks with 0% (Ink A) and 15% (Ink B) soy polyester (or 18.3% if only the vehicle is considered and not the pigment) were compared, the results demonstrated that Ink B required only slightly more energy for mar free (and/or thumb twist) cure at each of the four thicknesses.

As was observed for the clear films described in the preceding examples, a generic soy polyester ink, Ink B, produces a softer print film than non-soy polyester Ink A. Ink B also has a slight decrease in gloss with no effect on its optical density. However, it did provide excellent pigment wetting. It also developed color and gloss in a faster and more rapid dispersion, with less energy input then the non-polyester formulation. Its tinting strength was about 6% stronger then the comparative non-soy ink (Ink A). Thus, coating formulations of the present invention comprising polyester in partial replacement of acrylate provide a manufacturing improvement to relevant ink production.

TABLE 5a
Formulations of Magenta Inks

| Components | Ink A | Ink B |
|---|---|---|
| Soy polyester | 0% | 15% |
| Bisphenol A epoxydiacrylate^{2a} | 11.1% | 11.1% |
| Polyesteracrylate^{2b} | 44.9% | 29.9% |
| Propoxylated glycerol triacrylate^{2c} | 16% | 16% |
| Photoinitiator package | 10% | 10% |
| Pigment³ | 18% | 18% |

¹Degen Oil 4632 isophthalic acid, long oil
²UCB Chemical, Smyrna, GA, RadCure Products: 2a - Ebecryl 3720; 2b - Ebecryl 870; 2c - OTA 480 (now Cytec Surface Specialities)
³CIBA Irgalite Calcium Rubine L4BD

TABLE 5b
UV Curing of Magenta Ink
Orange Proofer Prints (IGT) on Coated Paper (Leneta 3NT-3)

| | | | Energy | Optical | | MEK |
|---|---|---|---|---|---|---|
| | | Film | Tack Free | Density | | Resistance |
| | Visc.¹ | Thickness | Cure | 60° Gloss | | (4% in |
| INK | (Poise) | (μm) | (mJ/cm⁻²)² | O.D. | % | IPA)³ |
| A | 150 | 1.3 | 180 | 1.81 | 49 | no bleed |
| (No | | 1.5 | 180 | 1.75 | 38 | |
| Polyester | | 3.3 | 110 | 2.40 | 55 | |
| present) | | 4.8 | 75 | 2.33 | 50 | |
| B | 150 | 1.4 | 220 | 1.82 | 39 | slight bleed |
| (Polyester | | 1.5 | 220 | 1.76 | 32 | |
| present) | | 3.4 | 220 | 2.34 | 39 | |
| | | 5.3 | 110 | 2.32 | 34 | |
| ¹Laray Falling Rod Viscometer at 25° C. and 2500 sec⁻¹ | | | | | | |
| ²The recorded energy data are based on a radiometer determination, UVmap plus, EIT, Inc., Sterling, VA, obtained on the UV setup that utilizes a 3Ø Fusion/AETEK UV Curing System with an H lamp attached to a variable speed conveyor belt and the lamp set at either low, medium or high energy setting. The peak intensity UVA (220-290 nm) at the low lamp | | | | | | |
| # setting (200 watts) was 2.776 watts/cm², medium lamp setting (300 watts) 4.449 watts/cm², high lamp setting 5.900 watts/cm². Cure identified by the application of the thumb twist and the tongue depressor mar resistance tests. | | | | | | |

³Five double rubs. Proposed ASTM test is now under experimental review.

As is well known in the art, ink formulations as shown in Table 5a require a prior two part mixing, each part with a specific formulation identified as a pre-dispersion and a letdown. Mixing of these two parts provides a reproducible method to make this type of ink. Thus, in the next set of experiments, pre-dispersions were prepared on a water-cooled three-roll mill and the letdowns, containing the photoinitiator and additional oligomer and monomer, were prepared by manual mixing. The formulations of the pre-dispersions and the letdowns are shown in Table 5c.

TABLE 5c
Pre-dispersion and Letdown Formulations

| | Pre-dispersion | | Letdown | |
|---|---|---|---|---|
| Components | Ink A | Ink B | Ink A | Ink B |
| Soy Polyester | 0 | 20.9 | 0 | 0 |
| Bisphenol A epoxydiacrylate^{2a} | 12.7 | 9.2 | 0.7 | 1.6 |
| Polyesteracrylate^{2b} | 51.0 | 36.8 | 2.7 | 1.2 |
| Propoxylated glycerol triacrylate^{2c} | 11.3 | 8.1 | 28.2 | 36.3 |
| Photoinitiator package | 0 | 0 | 13.9 | 13.9 |
| Pigment³ | 25 | 25 | 0 | 0 |

¹Degen Oil 4632 isophthalic acid, long oil
²UCB Chemical, Smyrna, GA, RadCure Products, 2a - Ebecryl 3720, 2b - Ebecryl 870, 2c - OTA 480 (now Cytec Surface Specialities)
³CIBA Irgalite Calcium Rubine L4BD

The oligomeric acrylate resins described in the preceding Examples are common resin type products utilized in the coatings and printing industry when UV/EB processing is utilized.

### Example 6

### Fatty Acid Process

A fatty acid process for producing polyesters utilizes fatty acid mixtures derived from different sources, as described previously. One fatty acid mixture is obtained from saponification of oxidizable triglyceride oils such as seed oils, of which soybean oil is one example; these triglycerides typically contain about 90% of a mixture of oleic, linoleic and linolenic acids. Fatty acid mixtures can also be obtained as a result of the pulping process for making paper, and these acids are called tall oil fatty acids (TOFA). (Tall is the Swedish word for pine.) The fatty acid composition of TOFA is fairly similar to that of fatty acids derived from commodity soybean oil. Both soybean oil and TOFA (North American sourced) contain about 25-35% or more of oleic acid, about 40-50% of linoleic acid, and about 5% of linolenic acid. Therefore, it is contemplated that these TOFA can also be used in the fatty acid process for producing generic polyesters that are generally comparable to those obtained from triglyceride oils such as soybean oil. Utilization of TOFA provides a cost advantage, as TOFA are generally less costly than the fatty acid mixtures obtained by the direct saponification of the oxidizable triglycerides. (See Z. W. Wicks, Jr., F. N. Jones, S. P. Pappas, “Organic Coatings: Science and Technology”, 2nd Ed., 1999, p. 278-279).

The fatty acid process, using the fatty acid mixtures from either source, is preferably used when a polyol other than glycerol (for example, pentaerythritol (PE)) is employed in the preparation of the generic polyesters. When the fatty acids are used in cook preparations, the polyol, fatty acids, and dibasic acid are all added at the start of the procedure. The subsequent polyesterification reaction, nominally carried out in the range of about 220 to 255° C., is completed more rapidly then the two step monoglyceride process.

The results of UV curing of coating formulations comprising commercial polyester resins prepared by the fatty acid process are shown in Tables 6 and 7. These polyester resins are ‘neat’ resins, in that they contain no added or carrier reducing solvents. The UV response of the coating formulations is similar to that observed for polyesters produced by the monoglyceride process. The cure response results of formulations shown in Tables 6a and 6b show cure rate enhancement over an essentially identical formulation in which the polyester is not present. While it is not necessary to understand the underlying mechanism, and the invention is not intended to be limited to any particular mechanism, it is hypothesized that the reactivity of the side group fatty acid functionalized polyester chains resides in the fatty acid moiety unsaturation and results in a synergistic interaction with the oligomeric acrylates in the formulation, resulting in the observed cure rate.

TABLE 6a
Polyester functionalized with soy based fatty acid as a side chain.
A partial replacement of polyesteracrylate in a single component
formulation.

| | | Cure Energy^{b} |
|---|---|---|
| Formulation components | Formulation ratio | mJ/cm² |
| Polyester acrylate^{c} | 100/0 | 373 |
| Polyester acrylate^{c}/Polyester allkyd^{d} | 85/15 | 235 |

a) Each formulation had added 0.5% of photoinitiator 2-hydroxy-2-methyl-1-phenyl-1-propanone (Ciba Daracure 1173).
^{b}The recorded energy data are from a radiometer (UV power plus, EIT, Inc., Sterling, VA) determination, obtained on the UV setup that uses a 3Ø Fusion AETEK UV Curing System with an H lamp configured over a variable speed-conveyor belt, and is based on the energy at 220-290 nm with the lamp at high power (400 watts/inch) with a reading at 50 ft/min of 467 mJ/cm², at medium power (300 watts/inch) 373 mJ/cm² and 235 mJ/cm² at low power (200 watts/inch).
^{c}UCB, Smyrna, GA, polyester acrylate 870
^{d}AKA1317 70 oil length pentaerythritol based, terephthalic acid based AKZO Nobel, Matteson, IL

TABLE 6B
Polyesters functionalized with side chain soy fatty acids as a partial replacement
in polyfunctional monomer containing polyesteracrylate formulations.
Each formulation contained 20% tripropyleneglycol diacrylate (TRPGDA) and 5% CIBA
Irgacure 500 and the amount of acrylate resin and polyester as given in the table.

| | ‘Neat’ Resin Properties | | | | Cure | | KMnO₄ | |
|---|---|---|---|---|---|---|---|---|
| Polyester | Polyol/acid | | Acrylate Resin | | Energy^{b} | Sward | Stain | MEK |
| resins^{a} | components | Amt. | Polyester | Amt. | mJ/cm² | Hardness | (O.D.)^{c} | resistance |
| AKA | Trimethylolpropane/ | 15% | UCB 870^{d} | 60% | 325 | 28 | 28 | Swell |
| 1163 | Terephthalic | 25% | ″ | 50% | 325 | 24 | | ″ |
| AKA | Pentaerithritol/ | 15% | ″ | 60% | 325 | 28 | 0.01 | ″ |
| 1317 | Terephthalic | 25% | ″ | 50% | 325 | 25 | 0.01 | ″ |
| AKA | Trimethylolpropane/ | 15% | ″ | 60% | 325 | 37 | 0.01 | ″ |
| 1008 | Iso-phthalic | 25% | ″ | 50% | 325 | 22 | 0.03 | ″ |
| no soy | | | ″ | 75% | 470 | 49 | 0.03 | No swell |
| polyester | | | | | | | | |

^{a}KZO Nobel, Matteson, IL
^{b}See footnote b Table 1, Part I
^{c}Optical density measurement (Hunterlabs Multipurpose Glossmeter)
^{d}UCB, Smyrna, GA, polyesteracrylate 870

Other types of fatty acid functionalized chain structures provided by a related fatty acid process are the epoxy esters. The fatty acids react with the epoxide on the potential epoxy advancing chain, releasing a fatty acid functionalized epoxy chain and its associating hydroxyl group. The results from two exemplary formulations are shown in Table 7. The epoxy esters contribute hardness to the film and are known to improve film adhesion. Such formulations are contemplated to serve as useful primers for metals, and for wood. They are reported to have excellent exterior properties.

TABLE 7
‘Neat’ (non-solvent containing) tall oil fatty acid based polyesters
and epoxides as a partial replacement (15%) for polyesteracrylate
in a polyfunctional monomer containing formulations.
Each formulation contained 20% tripropyleneglycol diacrylate
(TRPGDA) and 5% CIBA Irgacure 500 and the amount of
polyester acrylate resin and polyester or epoxy ester
as shown in the table.

| | | Polyester | Cure | Sward | KMnO₄ | MEK |
|---|---|---|---|---|---|---|
| Commercial | | Acrylate^{a} | energy^{b} | Hard- | soln. | resist- |
| Alkyd Resin | Amt. | (amt.) | mJ/cm² | ness | (O.D.)^{c} | ance |
| Ohio Polymer^{d} | 15% | 60% | 470 | 31 | 0.02 | Swell |
| 7276-100 | 25 | 50 | 470 | 26 | 0.06 | Swell |
| (conventional) | 35 | 40 | 470 | not | (0.04) | |
| | | | | cured | | |
| Ohio Polymer^{d} | 15% | 60% | 470 | 42 | 0.00 | Sl. |
| 7525 | | | | | | Swell |
| (conventional) | 25 | 50 | 470 | 34 | 0.02 | Swell |
| | 35 | 40 | 470 | 31 | 0.03 | swell |
| Ohio Polymer^{d} | 15% | 60% | 470 | 49 | 0.00 | Swell |
| 7499-10-50 | | | | | | |
| (Epoxy ester) | | | | | | |
| CCP^{e} | 15% | 60% | 470 | 49 | 0.00 | Sl. |
| 16-0119 | | | | | | swell |
| (Epoxy ester) | | | | | | |
| No Polyester | | 75% | 470 | 49 | 0.03 | No |
| | | | | | | swell |

^{a}See footnote c, Table 6a
^{b}Footnote b Table 1, Part I
^{c}Hunterlabs Multipurpose Glossmeter
^{d}OPC Polymers, Columbus, OH
^{e}CCP, Kansas City, MO 64141-6389

### Example 7

### Effects of Polyesters in Pigment Wetting and Dispersion of Pigments in Energy Curable Formulations

### Improved Dispersion of Phthalo Blue

The effect of polyesters in pigment wetting and dispersion of pigments in energy curable formulations of the present invention were examined.

Gloss readings have been identified as an efficient method to compare degrees of pigment dispersion. Test specimens of pigment pre-dispersions were prepared by manually stirring a pigment mixture into a formulation of the present invention, and then further dispersed by means of a Hoover Muller. The Hoover Muller allows a reproducible comparative dispersion treatment of vehicle pigment mixtures. It consists of two circular ground glass plates 7 inches in diameter. About 2 grams of a test specimen is placed on the lower plate. With the upper plate in contact with the pigment mixture on the lower plate, loads consisting of 50, 100, or 150 pounds may be placed on the upper plate reflecting the force on the mixture in the nip. In the test procedure, the upper plate was allowed to rotate for 1 min at 100 rpm for five passes sequentially at 50, 100, 150, 150 and 150 lbs, and a drawdown was made on a Grindometer. A Rhopoint Novo-Gloss Glossmeter determined the gloss. This Grindometer was a NPIRI Grindometer, a quality control piece of equipment primarily used to assess the degree of dispersion. It is particularly effective in the gloss measurement of the non-VOC wet film of a pre-dispersion. (The NPIRI gauge covers particles with a diameter between 2 and 25 μm).

The results are shown in Table 8.

TABLE 8
Effect of Polyesters on the Production of Pigment Pre-Dispersions
Grindometer Gloss Readings at 20°. Hoover Muller Third Pass

| | Pre-dispersion Formulations* | | |
|---|---|---|---|
| | | 70 oil length | 62 oil length |
| | | polyester | polyester |
| | No | (AKZO- | (McWhorter |
| Pigments | Polyester | Nobel 1317) | 50-5070) |
| Red (lithol rubine R57:1) gloss | 90 | 111 | 103 |
| reading | | | |
| % Gloss improvement versus | | 23% | 14% |
| no polyester | | | |
| Blue (Cyan B15:3) gloss | 66 | 70 | 78 |
| reading | | | |
| % Gloss improvement versus | | 6% | 18% |
| no polyester | | | |
| Yellow (diarylide AAMX Y13) | 69 | 84 | 92 |
| gloss reading | | | |
| % Gloss improvement versus | | 22% | 33% |
| no-polyester | | | |

*% Amounts of Predispersion Ingredients:

| | |
|---|---|
| 66.9% | Polyester Acrylate UCB 870 (or 46.0% + 20.9% soy |
| | polyester-alkyd) |
| 8.1% | OTA monomer UCB propoxylated glycerol triacrylate |
| 25.0% | Pigment |
| 100.0% | |

The results demonstrate that pre-dispersions comprising polyesters with soy fatty acid side chain branches increase the dispersion of each of the three common pigments. The 70 oil length polyester provided the best improvement for the most easily dispersed pigment, lithol rubine, while the 62 oil length polyester, with its apparent greater oxygen content, provides the best improvement for the more difficult dispersible blue and yellow pigments, with the yellow receiving the most favorable overall percentage boost.

These results also demonstrate that shorter oil polyester may be better dispersing agents then the longer oil length, as the 62 oil length polyester works best with the more difficult to disperse pigments. It is contemplated that further improvement in pigment dispersion will be obtained with polyesters of the same oil length but with reduced molecular weights.

### Example 8

### Effect of Polyesters in Pigment Wetting and in Dispersion of Pigment Energy Curable Formulations

### Commercially Available Polyester-Based Pigment Dispersions with Application to Metal Panels

Polyester-based pigment concentrates, as fine dispersions, are available from several manufacturers, purportedly offering an excellent dispersion with economy of use and high general compatibility. Until now, these products have often been used as constituents in conventional oxygen mediated curing materials, which include protective coatings and sealants, on wood and metal substrates. It is contemplated that these products can also be used in formulations of the present invention.

Several exploratory simplified formulations utilizing separately three manufacturer-sourced common pigment-polyester dispersions were prepared. The ratio of ingredients in the formulations, given in Table 9, reflects numerically the split of the concentrate into its polyester portion and the pigment portion. Table 10 identifies the percentage of pigment in each of the dispersions. The drawdowns were on glass and on steel panels.

TABLE 9
Pigmented Coatings Utilizing Commercial Polyester-Pigment Dispersions
(#3 wire wound yielded 10-14 μ drawdown thicknesses)

Formulations

| Ingredients | I | II | IIIa | IIIb |
|---|---|---|---|---|
| Polyester acrylate (870) | 52.6 | 56 | 67.5 | 67.5 |
| Long oil polyester | 13 | 14 | 14 | 14 |
| Glycerol propoxylated acrylate | 20.0 | 18.7 | 22.5 | 22.5 |
| (OTA) | | | | |
| Diarylide Yellow - Yellow 14¹⁾ | 4.3 | | | |
| Phthalo Blue (RS) - Blue 15:2 | | 6 | | |
| Carbon Black - Black 7 | | | 9.6 | 9.6 |
| Irgacure 500 | 10 | | 10 | |
| Photoinitiator Package²⁾ | | 4.9 | | 10 |
| Film Properties | | | | |
| Cure³ energy mJ/cm² | ˜700 | ˜900 | ˜700 | ˜700 |
| Sward Hardness | 4 | 4 | 13 | 7 |

¹Tends to wrinkle at thicker edges, a consequence of shrinkage associated with acrylate polymerization.
²A proprietary photoinitiator package was used. The less hardness developed in this system over Irgacure 500 needs to be further verified.
³Identified by thumb twist or tongue depressor mar resistance.

TABLE 10
Pigment Polyester Concentration

| Pigments | Concentration |
|---|---|
| Diarylide Yellow - Yellow 14 | 25% |
| Phthalo Blue (RS) - Blue 15:2 | 25% |
| Carbon Black - Black 7 | 30% |

In these experiments, the amount of polyester in each formulation was set at about 15% polyester plus about 5% pigment to approximate the exemplary vehicle formulations shown in Table 8. Thus, the three commercially available pigment dispersions, each with the same proprietary long oil polyester, were each formulated with the same oligomeric acrylate to make the three pigmented coating mixtures. The resulting UV cured films on glass and on steel panels were soft and required some extra energy compared to the previous similar formulations shown in Table 8.

Because the resulting films did show measurable cure and hardness, it is contemplated that simple modifications to the formulations of Table 10 will provide improved cure rates and hardness. Some factors to consider in improving the formulations follow. Although the proprietary long oil polyester has not be completely described by the manufacturer, it is known that the formulation used in the manufacturing process contained a dispersant agent or agents (ultimately to produce the finely dispersed product). The presence of these additives may retard the UV free radical curing capability, especially at the 15% polyester concentration (or identically a 20% concentration if the polyester plus pigment are numerically combined). Since these dispersions are nominally applied to coatings above 1 mil, for example at about 2 to 10 mils, there is less need to use a 15% polyester level (or 20% polyester plus pigment level) as good hiding power is obtained at the lower pigment levels. It is contemplated that cutting the concentration (polyester plus pigment) in half, from about 20% to about 10%, or to a third, to about 7%, will result in desired curability and hardness. Even at such lower concentrations, the use of dispersions comprising commercial polyester will be economically favorable, due to the decreased thickness of the formulation that may be applied to the surface.

If, however, corrosion protection is desired, as is often the case with metal panels, it is contemplated that alternate pigments and an increase in the amount of pigment will be beneficial. Also it is proposed that an alternate polyester, such as the 62 oil length alkyd (coded McWhorter 50-5070), is preferably used. This soy polyester is reported to have useful exterior properties and has shown efficient pigment dispersion specifically for difficult pigments, such as Phthalo Blue.

Thus, these results demonstrate that those polyesters and other backboned oil modified products, such as oil modified epoxy esters, can be used in pigment pre-dispersions, which can then be used in energy curable coating formulations. Such formulations include both printing and non-printing applications.

In summary, polyester products containing unsaturated fatty acid moieties can be used in energy curable formulations; such polyester products include long oil polyesters, medium oil polyesters, monomer modified polyesters, silicone modified polyesters and epoxy esters. It is contemplated that oxidizable oil modified polyurethanes may be useful, if obtained in the ‘neat’ or relatively ‘neat’ form, such as by solvent stripping or other means known or developed.

What is claimed is:

1. An energy curable coating formulation comprising an oligomeric acrylate and a polyester, where the oligomeric acrylate is a single type of oligomeric acrylate or a mixture of oligomeric types, and where the polyester is a single type of polyester or a mixture of polyesters.

2. The formulation according claim 1, where the relative proportion of the oligomeric acrylate and the polyester based on weight is:
a. from about 99% to about 50% for the oligomeric acrylate; and
b. from about slightly more than about 0% to about 50% for the polyester,
such that the proportion of polyester is about equal to or less than the proportion of oligomeric acrylate present and the total proportion of oligomeric acrylate and polyester together is about 100%.

3. The formulation according to claim 1, further comprising a multifunctional monomer, where the multifunctional monomer is a single type of monomer or a mixture of monomers.

4. The formulation according to claim 1, where the relative proportion of the oligomeric acrylate, the polyester, and the multifunctional monomer based on weight is:
a. from about 55% to slightly less than 100% for the oligomeric acrylate;
b. from about slightly more than 0% to about 50% for the polyester, such that the proportion is about equal to or less than the proportion of oligomeric acrylate present; and
c. from about 0% to about slightly less than about 45% for the multifunctional monomer,
such that the total proportion of oligomeric acrylate, polyester, and multifunctional monomer together is about 100%.

5. The formulation according to claim 1, further comprising a photoinitiator.

6. The formulation according to claim 3, further comprising a photoinitiator.

7. The formulation according to claim 1, further comprising at least one ingredient selected from the group consisting of monofunctional monomers, wetting agents, flow and/or leveling agents, fillers, and coloring components, where the ingredient comprises a single type of ingredient or a mixture of types of ingredients.

8. The formulation according to claim 3, further comprising at least one ingredient selected from the group consisting of monofunctional monomers, wetting agents, flow and/or leveling agents, fillers, and coloring components, where the ingredient is a single type of ingredient or a mixture of types of ingredients.

9. A method of preparing a coating formulation according to claim 1, comprising combining an oligomeric acrylate and a polyester.

10. A method of preparing a coating formulation according to claim 3, comprising combining an oligomeric acrylate, and a polyester, and a multifunctional monomer.

11. A method for forming a coating on a substrate, comprising
a. providing an energy curable coating formulation according to claim 1;
b. applying said formulation to a substrate; and
c. exposing said formulation to a source of radiation to resulting in an energy cured coating on the substrate.

12. A coating comprising a radiation cured formulation according to claim 1.

13. A coating prepared according to claim 11.

14. A radiation-polymerizable composition comprising an oligomeric acrylate and a polyester.

15. The composition according to claim 14, where the relative proportion of the oligomeric acrylate and the polyester based on weight is:
a. from about 99% to about 50% for the oligomeric acrylate; and
b. from about slightly more than about 0% to about 50% for the polyester,
such that the proportion of polyester is about equal to or less than the proportion of oligomeric acrylate present and the total proportion of oligomeric acrylate and polyester together is about 100%.

16. The composition according to claim 14 further comprising a multifunctional monomer.

17. The composition according to claim 16, where the relative proportion based on weight of the oligomeric acrylate, the polyester, and the multifunctional monomer is:
a. from about 55% to slightly less than 100% for the oligomeric acrylate;
b. from about slightly more than 0% to about 50% for the polyester, such that the proportion is about equal to or less than the proportion of oligomeric acrylate present; and
c. from about 0% to about slightly less than about 45% for the multifunctional monomer,
such that the total proportion of oligomeric acrylate, polyester, and multifunctional monomer together is about 100%.
